(19) United States
(12) Patent Application Publication
(10) Pub. No.: US 2016/0035610 A1
(43) Pub. Date: Feb. 4, 2016

(54) ELECTROSTATIC CHUCK ASSEMBLIES HAVING RECESSED SUPPORT SURFACES, SEMICONDUCTOR FABRICATING APPARATUSES HAVING THE SAME, AND PLASMA TREATMENT METHODS USING THE SAME

(71) Applicants: Myoung Soo Park, Seongnam-si (KR); Hakyoung Kim, Bucheon-si (KR); Junho Im, Suwon-si (KR); Jang Gyoo Yang, Seongnam-si (KR)

(72) Inventors: Myoung Soo Park, Seongnam-si (KR); Hakyoung Kim, Bucheon-si (KR); Junho Im, Suwon-si (KR); Jang Gyoo Yang, Seongnam-si (KR)

(21) Appl. No.: 14/803,833

(22) Filed: Jul. 20, 2015

(30) Foreign Application Priority Data
Jul. 30, 2014 (KR) 10-2014-0097540

(51) Int. Cl. H01L 21/683; H01J 37/32; H01L 21/67

(52) U.S. Cl. CPC H01L 21/6833; H01L 21/67069; H01J 37/32082

(57) ABSTRACT

An electrostatic chuck apparatus includes a base and a dielectric layer on the base. The dielectric layer includes a support surface opposite the base and a clamping electrode laterally extending along the support surface. The clamping electrode extends beyond an edge of the support surface such that the support surface is laterally recessed relative to the clamping electrode. The clamping electrode is configured to attract a substrate to the support surface by electrostatic force, and laterally extends along the support surface up to or beyond an edge of the substrate. Related electrostatic chuck assemblies, semiconductor fabricating apparatuses having the same, and plasma treatment methods using the same are also discussed.

### CROSS-REFERENCE TO RELATED APPLICATION

This U.S. non-provisional patent application claims priority under 35 U.S.C. §119 to Korean Patent Application No. 10-2014-0097540, filed on Jul. 30, 2014, in the Korean Intellectual Property Office, the disclosure of which is hereby incorporated by reference in its entirety.

### BACKGROUND

The inventive concepts relate to a chuck on which a wafer is mounted. More particularly, the inventive concepts relate to electrostatic chuck assemblies capable of improving temperature distribution, semiconductor fabricating apparatuses having the same, and plasma treatment methods using the same.

A wafer may be fixed or held on a chuck during a semiconductor fabricating process. For example, the wafer may be fixed or attracted to a surface using a clamp or a pressure difference. Recently, electrostatic chucks using electrostatic force have been increasingly used to perform a uniform thermal treatment on the wafer and to reduce or minimize occurrence of particles. In particular, to improve process uniformity, the temperature distribution of the wafer may be improved or a structure of a dielectric layer may be reformed.

### SUMMARY

According to some embodiments of the inventive concepts, an electrostatic chuck apparatus includes a base and a dielectric layer on the base. The dielectric layer includes a support surface opposite the base and a clamping electrode laterally extending along the support surface beyond an edge thereof.

In some embodiments, the edge of the support surface may define a stepped portion relative to a portion of the dielectric layer including the clamping electrode therein. For example, the dielectric layer may have a disk-shape, the support surface may have a first diameter, and the stepped portion may have a second diameter greater than the first diameter.

In some embodiments, a thickness of a portion of the dielectric layer between the support surface and the clamping electrode may be about 0.5 millimeters to about 4 millimeters.

In some embodiments, the electrostatic chuck apparatus may further include a dielectric focus ring on the dielectric layer adjacent the edge of the support surface. The dielectric focus ring may have a higher dielectric constant than the dielectric layer.

In some embodiments, the dielectric layer may be an electrostatic dielectric layer. The electrostatic chuck apparatus may further include a heater dielectric layer having a heater electrode between the electrostatic dielectric layer and the base.

In some embodiments, an interface between the electrostatic dielectric layer and the heater dielectric layer may be free of an adhesive and/or metal layer therebetween.

In some embodiments, the electrostatic chuck apparatus may further include a conductive heat distribution layer extending along an interface between the electrostatic dielectric layer and the heater dielectric layer adjacent the heater electrode.

In some embodiments, the heat distribution layer may have an electrical resistance of about 1 kilo-ohm or more between the clamping electrode and the heater electrode.

In some embodiments, the base may include a coolant channel therein and a temperature sensor adjacent the heater dielectric layer. An adhesive layer having a substantially uniform thickness may extend along an interface between the heater dielectric layer and the base.

In some embodiments, the adhesive layer may be a multi-layer stack including first and second adhesive layers having different thermal conductivities.

In some embodiments, the multi-layer stack may further include a metal plate extending between the first and second adhesive layers.

In some embodiments, the support surface may include a plurality of recesses therein. At least one gas channel may be coupled to the respective recesses in the support surface and may define a passage between the dielectric layer and the base to supply a heat-conductive gas to the respective recesses.

In some embodiments, the recesses may define different volumes for the heat-conductive gas in first and second regions of the support surface such that respective thermal conductivities of the first and second regions differ.

In some embodiments, the support surface may include a plurality of protrusions between ones of the recesses. The protrusions and recesses in the support surface may have different heights, spacings, and/or depths defining the different volumes in the first and second regions thereof.

In some embodiments, the clamping electrode may have a circular shape and/or comprises first and second electrodes arranged concentrically or side-by-side.

In some embodiments, the electrostatic chuck apparatus may be included in a plasma etching apparatus. The plasma etching apparatus may include a vacuum chamber including a support member therein, the support member having the electrostatic chuck apparatus thereon; a baffle plate between the electrostatic chuck apparatus and an inner sidewall of the vacuum chamber; an exhaust pipe at a lower portion of the vacuum chamber; a gate valve on an outer sidewall of the vacuum chamber; a dielectric window in the vacuum chamber spaced apart from the electrostatic chuck apparatus; an antenna room on the dielectric window, the antenna room having at least one antenna therein; a high-frequency or radio-frequency (RF) power source coupled to the at least one radio-frequency antenna; and a gas supply source configured to supply a treatment gas into the vacuum chamber via a supply unit at a sidewall of the vacuum chamber.

According to further embodiments of the inventive concepts, an electrostatic chuck apparatus includes a base and a dielectric layer on the base. The dielectric layer includes a support surface opposite the base and a clamping electrode therein configured to generate an electrostatic force to attract a substrate to the support surface. The support surface is laterally recessed relative to the clamping electrode.

In some embodiments, an edge of the support surface may define a stepped portion relative to a portion of the dielectric layer including the clamping electrode therein.

In some embodiments, the dielectric layer may have a disk-shape, and a dielectric focus ring may extend along the edge of the support surface on the portion of the dielectric layer including the clamping electrode therein. The dielectric focus ring may have a higher dielectric constant than the dielectric layer.

In some embodiments, the dielectric layer may be an electrostatic dielectric layer. The electrostatic chuck apparatus may further include a heater dielectric layer having a heater electrode between the electrostatic dielectric layer and the base. An interface between the electrostatic dielectric layer and the heater dielectric layer may be free of an adhesive and/or metal layer therebetween.

In some embodiments, the electrostatic chuck apparatus may further include an adhesive layer having a substantially uniform thickness extending along an interface between the heater dielectric layer and the base. The adhesive layer may be a multi-layer stack including first and second adhesive layers having different thermal conductivities.

In some embodiments, the multi-layer stack may further include a metal plate extending between the first and second adhesive layers. The first and second adhesive layers may include a heat-conductive material including heat-conductive fillers suspended therein. The heat-conductive fillers may define a continuous matrix in the first adhesive layer and a discontinuous matrix in the second adhesive layer, or the first and second adhesive layers may include different materials and/or different thicknesses.

In some embodiments, the support surface may include a plurality of recesses therein that define different volumes for a heat-conductive gas in first and second regions of the support surface, such that respective thermal conductivities of the first and second regions may differ. The support surface may further include a plurality of protrusions between ones of the recesses. The protrusions and recesses in the first and second regions of the support surface may have different heights, spacings, and/or depths defining the different volumes in the first and second regions thereof.

According to still further embodiments of the inventive concepts, an electrostatic chuck apparatus includes a base and a dielectric layer on the base. The dielectric layer includes a support surface opposite the base and a clamping electrode configured to attract a substrate to the support surface by electrostatic force. The clamping electrode laterally extends along the support surface up to or beyond an edge of the substrate.

In some embodiments, the edge of the substrate may laterally extend beyond an edge of the support surface.

In some embodiments, the edge of the support surface may define a stepped portion relative to a portion of the dielectric layer including the clamping electrode therein.

In some embodiments, the dielectric layer may have a disk-shape, and a dielectric focus ring having a higher dielectric constant than the dielectric layer may extend along the edge of the support surface between the clamping electrode and the substrate. For example, the dielectric focus ring may have a dielectric constant of about 3 or more, a resistivity of about 100 ohm-centimeters or less, and/or a surface adjacent the support surface with a surface roughness of about 0.8 micrometers or less.

In some embodiments, recesses in first and second regions of the support surface may define different volumes for a heat-conductive gas such that respective thermal conductivities of the first and second regions may differ.

Other devices and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

The inventive concepts will become more apparent in view of the attached drawings and accompanying detailed description.

FIG. 1 is a cross-sectional view illustrating an electrostatic chuck assembly or apparatus according to some embodiments of the inventive concepts;

FIG. 2A is a cross-sectional view illustrating a portion of FIG. 1;

FIG. 2B is an enlarged cross-sectional view of a portion of FIG. 2A;

FIG. 2C is a cross-sectional view illustrating a comparison example of FIG. 2B;

FIG. 2D is an enlarged plan view illustrating a portion of FIG. 2B;

FIGS. 2E and 2F are plan views illustrating modified embodiments of FIG. 2D;

FIG. 2G is a cross-sectional view illustrating a modified embodiment of FIG. 2B;

FIGS. 3A to 3C are cross-sectional views illustrating methods of forming a heater electrode according to some embodiments of the inventive concepts;

FIG. 3D is a cross-sectional view illustrating a modified embodiment of FIG. 3C;

FIGS. 4A to 4C are cross-sectional views illustrating methods of forming a heater electrode according to other embodiments of the inventive concepts;

FIGS. 5A to 5E are cross-sectional views illustrating methods of forming an electrostatic chuck according to some embodiments of the inventive concepts;

FIGS. 6A to 6C are cross-sectional views illustrating methods of forming an electrostatic chuck according to other embodiments of the inventive concepts;

FIGS. 7A to 7C are cross-sectional views illustrating methods of forming an electrostatic chuck according to still other embodiments of the inventive concepts;

FIGS. 8A to 8C are cross-sectional views illustrating methods of forming an electrostatic chuck according to yet other embodiments of the inventive concepts;

FIG. 9 is a cross-sectional view illustrating an electrostatic chuck assembly or apparatus according to other embodiments of the inventive concepts;

FIG. 10A is a cross-sectional view of a portion of FIG. 9;

FIG. 10B is an enlarged cross-sectional view of a portion of FIG. 10A;

FIG. 10C is a cross-sectional view illustrating a modified embodiment of FIG. 10B;

FIG. 11A is a plan view illustrating an electrostatic dielectric layer according to some embodiments of the inventive concepts;

FIGS. 11B and 11C are cross-sectional views of FIG. 11A;

FIG. 11D is a plan view illustrating a modified embodiment of FIG. 11A;

FIG. 12A is a plan view illustrating an electrostatic dielectric layer according to other embodiments of the inventive concepts;

FIGS. 12B and 12C are cross-sectional views of FIG. 12A;

FIG. 12D is a plan view illustrating a modified embodiment of FIG. 12A;

FIG. 13A is a plan view illustrating an electrostatic dielectric layer according to still other embodiments of the inventive concepts;

FIGS. 13B and 13C are cross-sectional views of FIG. 13A;

FIG. 13D is a plan view illustrating a modified embodiment of FIG. 13A;

FIGS. 14A and 14B are cross-sectional views illustrating an electrostatic dielectric layer according to yet other embodiments of the inventive concepts;

FIGS. 15A and 15B are cross-sectional views illustrating an electrostatic dielectric layer according to yet still other embodiments of the inventive concepts; and

FIG. 16 is a cross-sectional view illustrating a semiconductor fabricating apparatus including an electrostatic chuck according to embodiments of the inventive concepts.

### DETAILED DESCRIPTION OF THE EMBODIMENTS

The inventive concepts will now be described more fully hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concepts. Accordingly, shapes of the exemplary views may be modified according to manufacturing techniques and/or allowable errors. Therefore, the embodiments of the inventive concepts are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concepts explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described, herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

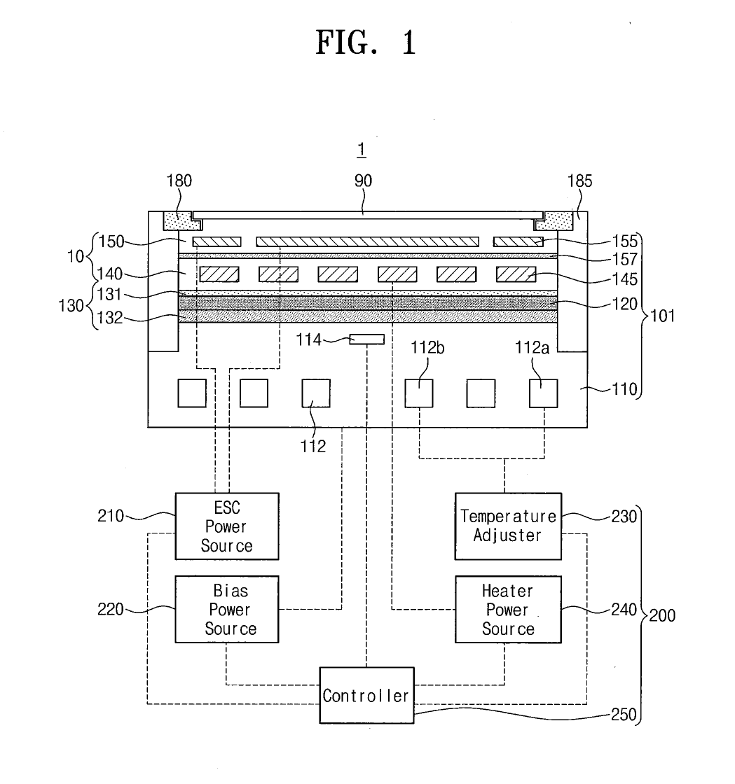

FIG. 1 is a cross-sectional view illustrating an electrostatic chuck assembly or apparatus according to some embodiments of the inventive concepts.

Referring to FIG. 1, an electrostatic chuck assembly or apparatus 1 may include an electrostatic chuck 101 and a control part 200. The electrostatic chuck 101 may adsorb or attract a substrate 90 (e.g., a silicon wafer) to a surface thereof (also referred to herein as a “support surface”) by electrostatic force, and the control part 200 may control operation of the electrostatic chuck 101.

The electrostatic chuck 101 may include a body or base 110 and a dielectric stack structure 10. The dielectric stack structure 10 may be adhered to the base 100 by an adhesive layer 130. The dielectric stack structure 10 may include a heater dielectric layer 140 and an electrostatic dielectric layer 150 that are sequentially stacked on the base 110. The adhesive layer 130 may have a double-layered structure that includes a first adhesive 131 and a second adhesive 132. In addition, a metal plate 120 may be disposed between the first adhesive 131 and the second adhesive 132.

The base 110 may have a disk shape and may be formed of metal such as aluminum (Al), titanium (Ti), stainless steel, tungsten (W), or any alloy thereof. The electrostatic chuck 101 may be used in a plasma treatment apparatus that treats the substrate 90 using plasma. If high-temperature environment is created in the inside of a chamber having the electrostatic chuck 101 and the substrate 90 is exposed to high-temperature plasma, damage (e.g., ion bombardment) may be applied to the substrate 90. It may be required or helpful to cool the substrate 90 to reduce or prevent the damage of the substrate and perform a uniform plasma treatment. A channel 112 through which a coolant flows may be provided in the base 110 to cool the substrate 90. For example, the coolant may include at least one of water, ethylene glycol, silicon oil, liquid Teflon, or a mixture of water and glycol.

The channel 112 may have a pipe structure which is concentrically or helically arranged about a central axis of the base 110. The channel 112 may include an inlet 112a and an outlet 112b. The coolant may flow into the channel 112 through the inlet 112a and may flow out from the channel 112 through the outlet 112b. The inlet 112a and the outlet 112b may be connected to a temperature adjuster 230 of the control part 200. A flow speed and a temperature of the coolant circulating through the channel 112 may be adjusted by the temperature adjuster 230.

The base 110 may be electrically connected to a bias power source 220 of the control part 200. A high-frequency or radio-frequency power may be applied from the bias power source 220 to the base 110 such that the base 110 may act as an electrode for generating plasma.

The base 110 may further include a temperature sensor 114. The temperature sensor 114 may transfer a measured temperature of the base 110 to a controller 250 of the control part 200. A temperature of the electrostatic chuck 101 (e.g., a temperature of the electrostatic dielectric layer 150 or substrate 90) may be predicted or otherwise determined based on the temperature measured from the temperature sensor 114.

The heater dielectric layer 140 may include an embedded heater electrode 145. For example, the heater dielectric layer 140 may be formed of dielectric such as ceramic (e.g., Al₂O₃, AlN, or Y₂O₃) and/or resin (e.g., polyimide). The heater dielectric layer 140 may have, for example, a disk shape. In some embodiments, the heater dielectric layer 140 may be formed of resin such as polyimide. The heater electrode 145 may be formed of a conductive material such as metal (e.g., tungsten (W), copper (Cu), nickel (Ni), molybdenum (Mo), titanium (Ti), a nickel-chrome (Ni—Cr) alloy, and/or a nickel-aluminum (Ni—Al) alloy) and/or a conductive ceramic material (e.g., tungsten carbide (WC), molybdenum carbide (MoC), or titanium nitride (TiN)). The heater electrode 145 may be electrically connected to a heater power source 240 of the control part 200. Since the heater electrode 145 generates heat by power (e.g., an AC voltage) provided from the heater power source 240, the temperature of the electrostatic chuck 101 or substrate 90 may be adjusted. In some embodiments, the heater electrode 145 may have a pattern which is concentrically or helically arranged about a central axis of the heater dielectric layer 140.

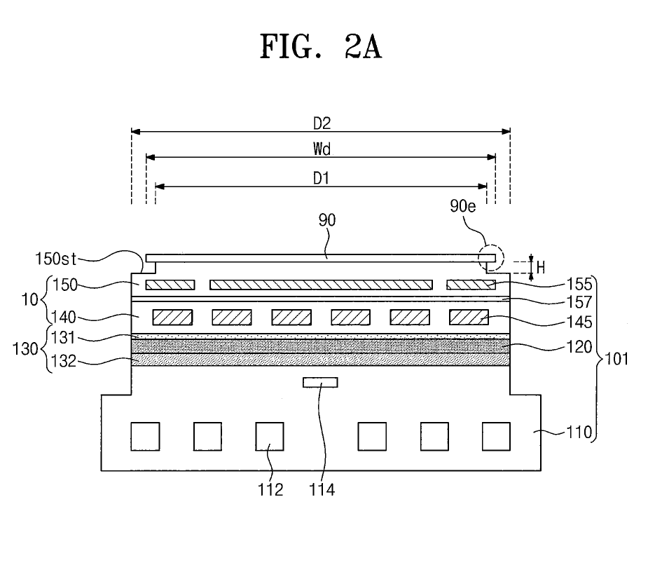

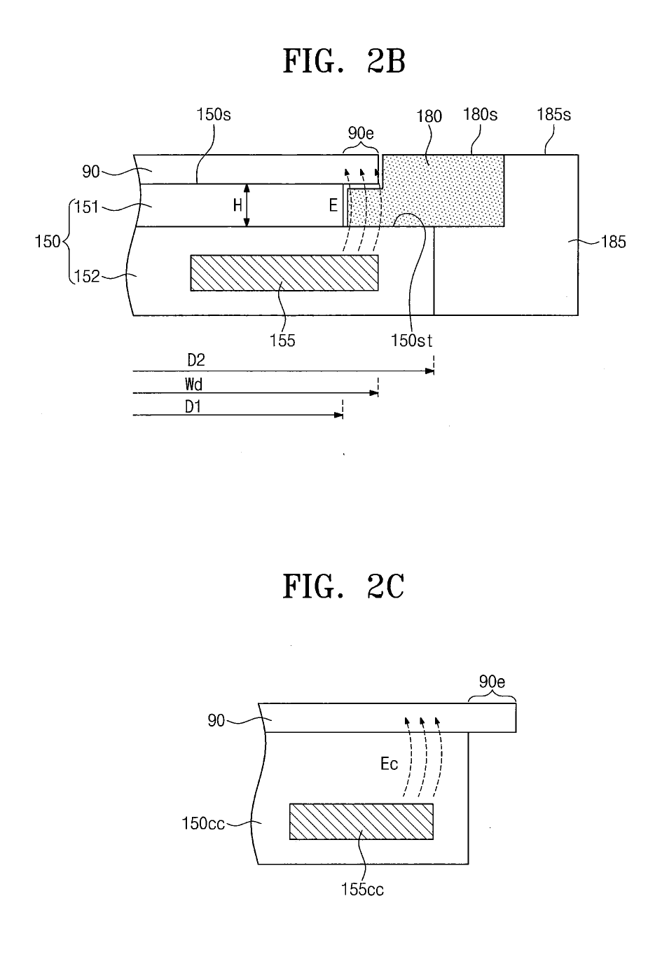

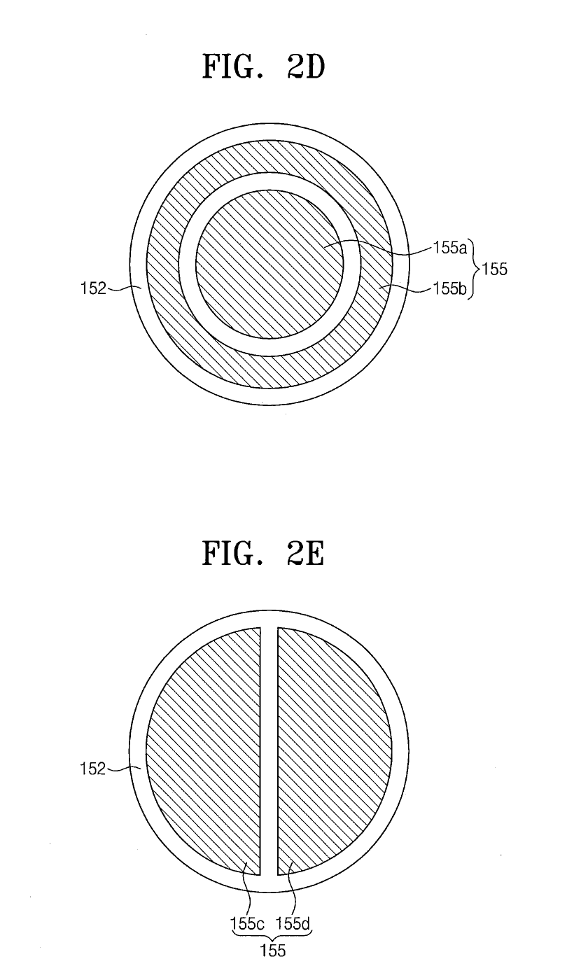

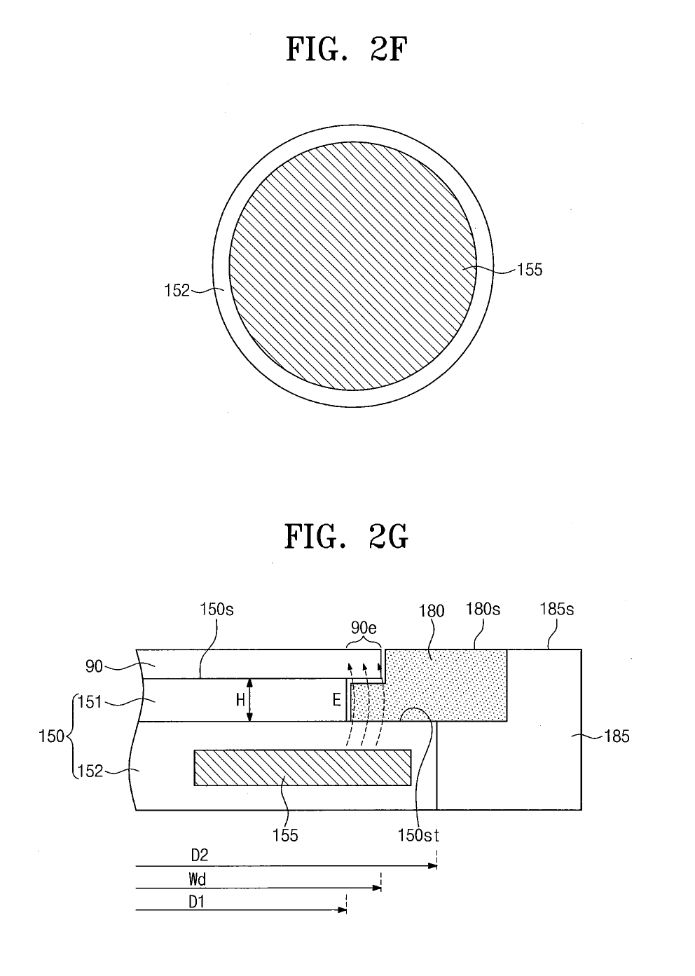

The electrostatic dielectric layer 150 may include an embedded adsorption or clamping electrode 155. For example, the electrostatic dielectric layer 150 may be formed of dielectric such as ceramic (e.g., Al₂O₃, AlN, or Y₂O₃) and/or resin (e.g., polyimide). For example, the electrostatic dielectric layer 150 may have a disk shape. The substrate 90 may be disposed on the electrostatic dielectric layer 150. The adsorption or clamping electrode 155 may be formed of a conductive material such as metal (e.g., tungsten (W), copper (Cu), nickel (Ni), molybdenum (Mo), a nickel-chrome (Ni—Cr) alloy, and/or a nickel-aluminum (Ni—Al) alloy) and/or a conductive ceramic material (e.g., tungsten carbide (WC), molybdenum carbide (MoC), or titanium nitride (TiN)). The adsorption or clamping electrode 155 may be electrically connected to an electrostatic chuck (ESC) power source 210 of the control part 200. Electrostatic force may occur between the adsorption or clamping electrode 155 and the substrate 90 by power (e.g., a direct current (DC) voltage) provided from the ESC power source 210, and thus, the substrate 90 may be adsorbed or attracted or fixed on the electrostatic dielectric layer 150. The adsorption or clamping electrode 155 may have a combined structure of a circular pattern and a ring pattern, a circular shape, or a combined structure of two semicircular patterns, which will be described later with reference to FIGS. 2D to 2F.

In some embodiments, the dielectric stack structure 10 may further include a heat distribution layer 157 provided between the heater dielectric layer 140 and the electrostatic dielectric layer 150. The heat distribution layer 157 may have a heat conductivity of, for example, about 10 W/mK or more. For example, the heat distribution layer 157 may include at least one of aluminum nitride (AlN), boron nitride (BN), tungsten (W), or molybdenum (Mo). The heat distribution layer 157 may more uniformly distribute the heat generated from the heater electrode 145.

It may be advantageous to prevent an electrical short between the adsorption or clamping electrode 155 and the heater electrode 145. For example, an electrical resistance value between the adsorption or clamping electrode 155 and the heater electrode 145 may be about 1 kΩ or more. In other words, the electrostatic dielectric layer 150, the heater dielectric layer 140, and the heat distribution layer 157 may include a material capable of providing the electrical resistance value of about 1 kΩ or more between the adsorption or clamping electrode 155 and the heater electrode 145.

The ESC power source 210, the bias power source 220, the heater power source 240, and the temperature adjuster 230 may be controlled by the controller 250. For example, the controller 250 may read the temperature of the electrostatic chuck 101 and/or the substrate 90 based on the temperature measured from the temperature sensor 114 such that the power of the heater power source 240 may be controlled to adjust the amount of the heat generated from the heater electrode 145. As a result, the temperature of the electrostatic chuck 101 and/or the substrate 90 may be properly settled.

The electrostatic chuck 101 may include a focus ring 180 that extends along a circumference of the substrate 90 to surround the substrate 90. The focus ring 180 may have a ring shape. The focus ring 180 may be provided to improve uniformity of process treatment (e.g., a plasma etching) performed on the substrate 90. The focus ring 180 may include a material that has a dielectric constant of about 3 or more and/or a resistivity of 100 Ωcm or less. For example, the focus ring 180 may include at least one of quartz, Al₂O₃, Y₂O₃, silicon (Si), silicon carbide (SiC), carbon (C), or SiO₂. An outer ring 185 may be further provided to shield an outer sidewall of the electrostatic chuck 101. The outer ring 185 may be formed of material that is the same as or similar to the material of the focus ring 180.

According to the present embodiment, the electrostatic chuck 101 may have a stepped structure that is suitable for applying a substantially uniform electric field to the substrate 90. The heater electrode 145 may be formed by a patterning process described below, thereby improving the pattern reproducibility of the heater electrode 145. The electrostatic dielectric layer 150 may be combined with the heater dielectric layer 140 without an adhesive layer. The heater dielectric layer 140 may be combined with the base 110 by the adhesive layer 130 having the double-layered structure. Hereinafter, these will be described below in more detail.

FIG. 2A is a cross-sectional view illustrating a portion of FIG. 1. FIG. 2B is an enlarged cross-sectional view of a portion of FIG. 2A. FIG. 2C is a cross-sectional view illustrating a comparison example of FIG. 2B. FIG. 2D is an enlarged plan view illustrating a portion of FIG. 2B. FIGS. 2E and 2F are plan views illustrating modified embodiments of FIG. 2D. FIG. 2G is a cross-sectional view illustrating a modified embodiment of FIG. 2B.

Referring to FIG. 2A, the electrostatic dielectric layer 150 may have a step pattern 150st. In some embodiments, an upper sidewall of the electrostatic dielectric layer 150 may be recessed toward a central portion of the electrostatic chuck 150 to form the step pattern 150st. In other words, the electrostatic dielectric layer 150 may have the step pattern 150st illustrated in FIG. 2B. The electrostatic dielectric layer 150 may include an upper portion 151 on which the substrate 90 is mounted and a lower portion 152 within which the adsorption or clamping electrode 155 is embedded. The adsorption or clamping electrode 155 may protrude laterally beyond the upper portion 151. In the present specification, the phrase “the lower portion 152 protrudes” may mean that “the adsorption or clamping electrode 155 protrudes.”

A size or dimension of the upper portion 151 of the electrostatic dielectric layer 150 may be smaller that of the substrate 90. A size or dimension of the lower portion 152 of the electrostatic dielectric layer 150 may be greater than that of the upper portion 151. The size or dimension of the lower portion 152 of the electrostatic dielectric layer 150 may be substantially equal to or different from that of the substrate 90. In some embodiments, the term “size” may refer to a diameter.

For example, if the electrostatic dielectric layer 150 has the disk shape, the upper portion 151 may have a first diameter D1 and the lower portion 152 may have a second diameter D2 greater than the first diameter D1. The substrate 90 may have a diameter Wd greater than the first diameter D1. In other words, the size (e.g., the diameter) of the substrate 90 may be greater than that of the upper portion 151, and an edge 90e of the substrate 90 may protrude laterally beyond a sidewall of the upper portion 151 when the substrate 90 is mounted on the electrostatic dielectric layer 150. Since the upper portion 151 is covered or otherwise includes with the substrate 90 thereon, the upper, portion 151 or the electrostatic chuck 101 may be free of damages generated by, for example, a plasma treatment process. The second diameter D2 of the lower portion 152 may be substantially equal to or different from the diameter Wd of the substrate 90.

If the diameter Wd of the substrate 90 is about 300 mm, the first diameter D1 of the upper portion 151 may be in a range of about 296 mm to about 299 mm and the second diameter D2 of the lower portion 152 may be in a range of about 297 mm to about 340 mm. The heater dielectric layer 140 may have a disk shape of which a diameter is substantially equal to or similar to the second diameter D2 of the lower portion 152. A top end portion of the base 110 that is adjacent to the dielectric stack structure 10 may have a diameter that is substantially equal to or similar to the second diameter D2 of the lower portion 152. A height of the upper portion 151 (i.e., a height H of the step pattern 150st) may be in a range of about 0.5 mm to about 4 mm. That is, a thickness of a portion of the electrostatic dielectric layer 150 between the support surface and the clamping electrode 155 may be about 0.5 millimeters to about 4 millimeters.

Referring to FIG. 2B, the substrate 90 may be mounted on a flat or substantially planar surface 150s of the electrostatic dielectric layer 150. If power (e.g., a DC voltage) is applied to the adsorption or clamping electrode 155, the substrate 90 may be adsorbed or clamped on the electrostatic dielectric layer 150 by an electrostatic force. Since the electrostatic dielectric layer 150 has the step pattern 150st, the lower portion 152 may protrude laterally from the upper portion 151. Thus, the adsorption or clamping electrode 155 may protrude laterally along the support surface beyond the sidewall of the upper portion 151, and an edge of the adsorption or clamping electrode 155 may be extend up to and/or beyond the edge 90e of the substrate 90. Since the edge of the adsorption or clamping electrode 155 substantially overlaps with the edge 90e of the substrate 90, an electric field E may be easily applied to the edge 90e of the substrate 90. Alternatively, as shown in FIG. 2G, the edge of the adsorption or clamping electrode 155 may extend toward a sidewall of the lower portion 152 beyond the edge 90e of the substrate 90.

On the other hand, if an electrostatic dielectric layer 150cc does not have a step pattern and an adsorption or clamping electrode 155cc does not protrude as illustrated in FIG. 2C, it may be difficult to apply an electric field Ec to the edge 90e of the substrate 90.

According to the present embodiment, the intensity of the electric field E applied to the edge 90e of the substrate 90 may be substantially equal to or similar to that of the electric field E applied to, for example, a center and/or a portion adjacent thereto of the substrate 90. Since the electric field E is uniformly applied to the substrate 90, a uniform adsorption or clamping force may be provided to the substrate 90. In addition, a uniform plasma density may be provided over the substrate 90, and/or the substrate 90 may be uniformly treated by a semiconductor fabricating process such as, for example, a plasma etching process.

The adsorption or clamping electrode 155 may be a bipolar type or a monopolar type. In some embodiments, as illustrated in FIG. 2D, the adsorption or clamping electrode 155 may be a bipolar type that includes an inner electrode 155a having a circular shape and an outer electrode 155b having a ring shape. The outer electrode 155b may protrude laterally from the sidewall of the upper portion 151, as illustrated in FIG. 2B. A positive voltage may be applied to one of the inner and, outer electrodes 155a and 155b, and a negative voltage may be applied to the other of the inner and outer electrodes 155a and 155b.

In other embodiments, as illustrated in FIG. 2E, the adsorption or clamping electrode 155 may be a bipolar type including a first semicircular electrode 155c and a second semicircular electrode 155d. The first and second semicircular electrodes 155c and 155d may be bilaterally symmetric. Edges of the first and second semicircular electrodes 155c and 155d may protrude from the sidewall of the upper portion 151, as illustrated in FIG. 2B. A positive voltage may be applied to one of the first and second semicircular electrodes 155c and 155d, and a negative voltage may be applied to the other of the first and second semicircular electrodes 155c and 155d.

In still other embodiments, as illustrated in FIG. 2F, the adsorption or clamping electrode 155 may be a monopolar type consisting of one circular electrode. A DC voltage may be applied to the adsorption or clamping electrode 155 to generate the electrostatic force.

The focus ring 180 may be disposed between the edge 90e of the substrate 90 and the lower portion 152. The intensity of the electric field E applied to the edge 90e of the substrate 90 may be varied according to the dielectric constant of the focus ring 180. For example, the greater the dielectric constant of the focus ring 180, the stronger the intensity of the electric field E.

A surface 180s of the focus ring 180 may act as a particle source during a plasma process. Thus, the surface 180s of the focus 180 may be smooth to reduce or minimize or prevent particles. In some embodiments, the surface 180s of the focus ring 180 may have a surface roughness (Ra) of about 0.8 μm or less. If the outer ring 185 is further provided, a surface 185a of the outer ring 185 may have a surface roughness (Ra) of about 0.8 μm or less.

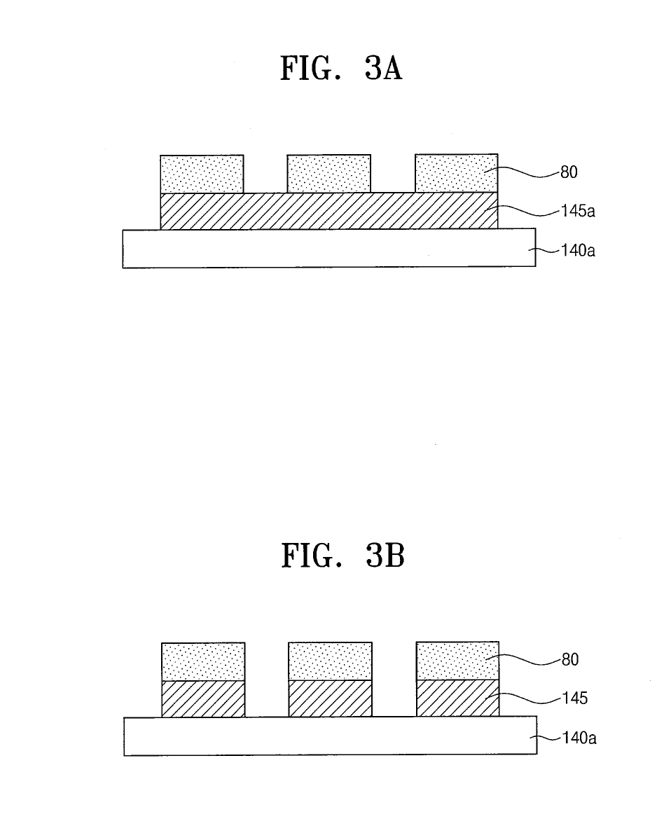

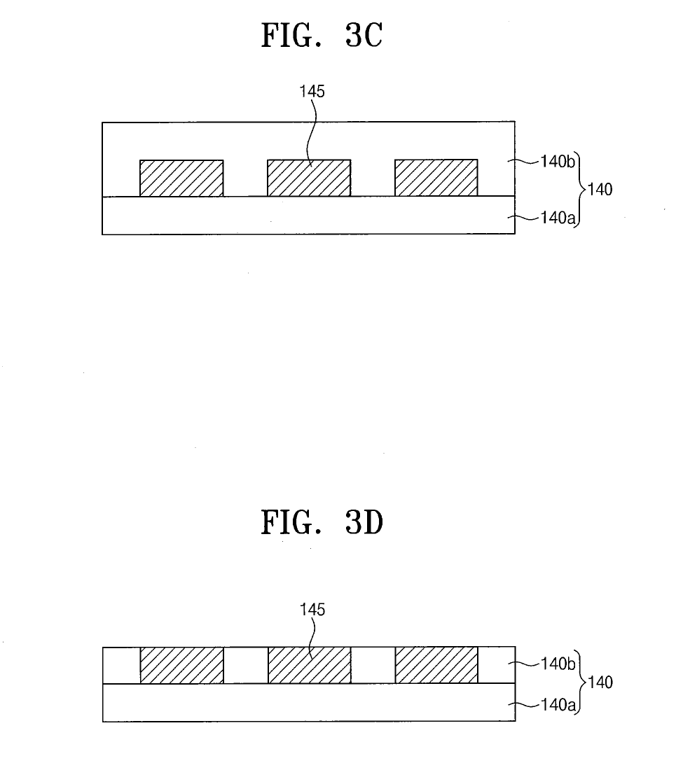

FIGS. 3A to 3C are cross-sectional views illustrating methods of forming a heater electrode according to some embodiments of the inventive concepts. FIG. 3D is a cross-sectional view illustrating a modified embodiment of FIG. 3C.

Referring to FIG. 3A, a conductor 145a may be formed on a first dielectric 140a, and a mask pattern 80 may be formed on the conductor 145a. In some embodiments, the conductor 145a may have a plate shape, and the mask pattern 80 may be a concentric or helical pattern that partially exposes the conductor 145a. The first dielectric 140a and/or the conductor 145a may be formed by a paste printing process, a plasma spray process, and/or a deposition process.

Referring to FIG. 3B, the conductor 145a may be patterned by an etching process using the mask pattern 80 as an etch mask. The conductor 145a may be formed into a heater electrode 145 by the etching process. The heater electrode 145 may have a concentric or helical pattern of which a center corresponds to a center of the first dielectric 140a. The mask pattern 80 may be removed after the etching process.

Referring to FIG. 3C, a second dielectric 140b may be formed on the first dielectric 140b. The second dielectric 140b may completely cover the heater electrode 145. The second dielectric 140b may be formed by a paste printing process, a plasma spray process, and/or a deposition process. The first dielectric 140a and the second dielectric 140b may constitute or define a heater dielectric layer 140. According to the present embodiment, the heater dielectric layer 140 having the embedded heater electrode 145 may be formed. In other embodiments, the second dielectric 140b may be formed to expose the heater electrode 145, as illustrated in FIG. 3D.

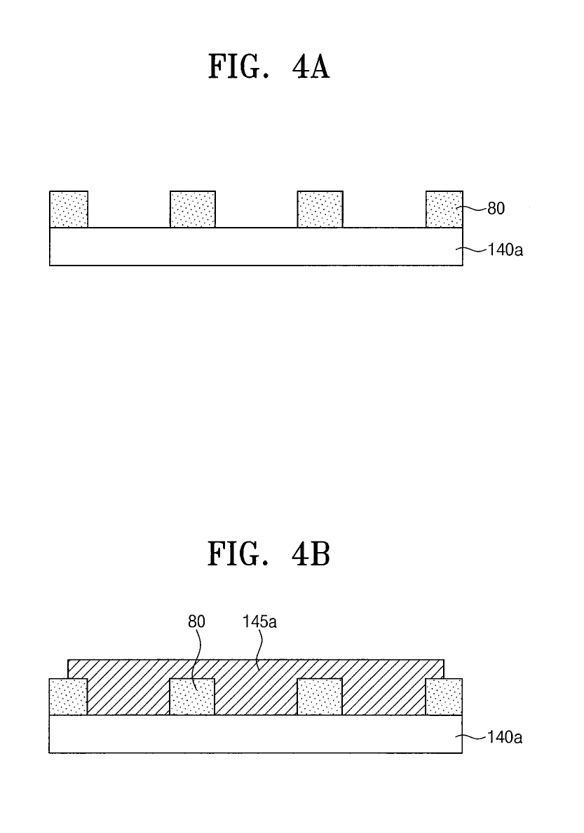

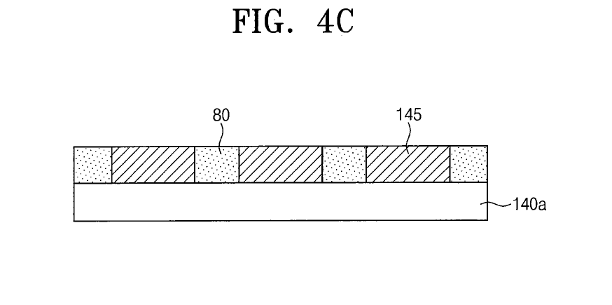

FIGS. 4A to 4C are cross-sectional views illustrating a method of forming a heater electrode according to other embodiments of the inventive concepts.

Referring to FIG. 4A, a mask pattern 80 may be formed on a first dielectric 140a. In some embodiments, the mask pattern 80 may not completely cover the first dielectric 140a. The mask pattern 80 may have a concentric or helical pattern.

Referring to FIG. 4B, a conductor 145a may be formed on the first dielectric 140a. The conductor 145a may cover at least a portion, which is not covered by the mask pattern 80, of the first dielectric 140a.

Referring to FIG. 4C, the conductor 145a may be planarized until the mask pattern 80 is exposed, thereby forming a heater electrode 145. The mask pattern 80 may be selectively removed after the formation of the heater electrode 145. Next, the second dielectric 140b may be formed as illustrated in FIG. 3C. Thus, the heater dielectric layer 140 having the embedded heater electrode 145 may be formed. In other embodiments, the second dielectric 140b may be formed to expose the heater electrode 145, as illustrated in FIG. 3D.

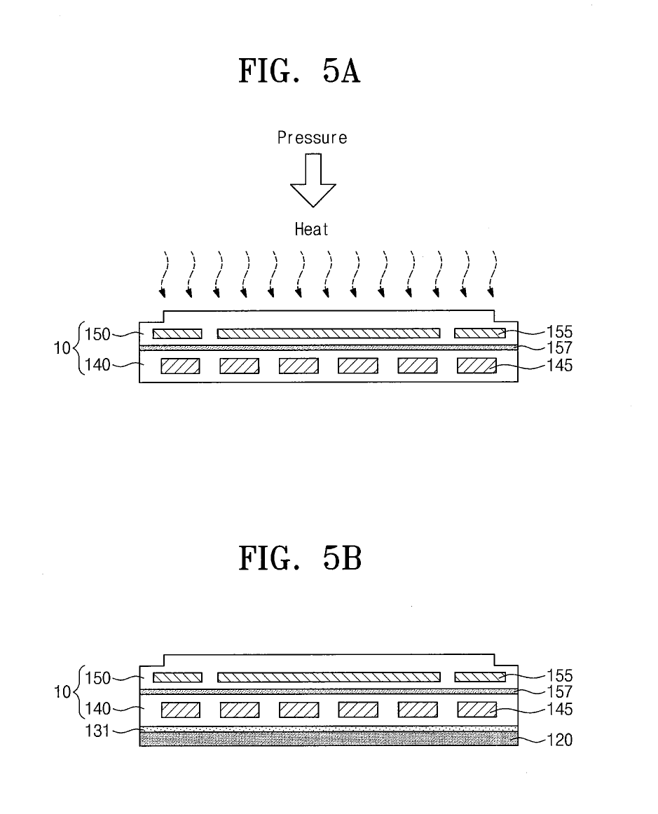

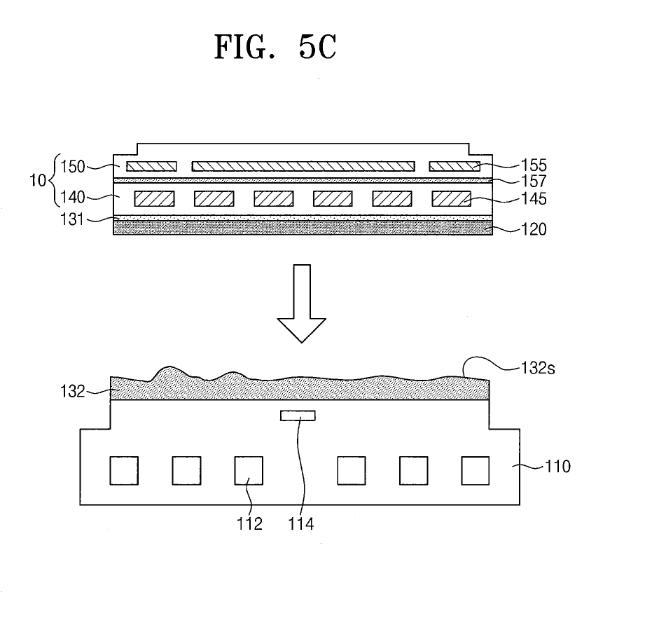

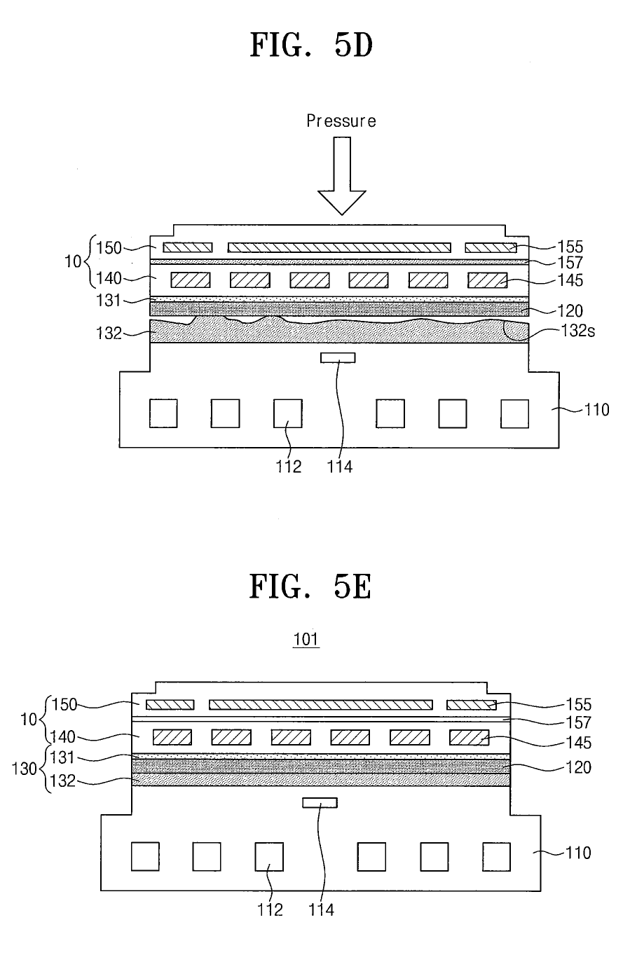

FIGS. 5A to 5E are cross-sectional views illustrating methods of forming an electrostatic chuck according to some embodiments of the inventive concepts.

Referring to FIG. 5A, a heater dielectric layer 140 having a heater electrode 145 may be combined with an electrostatic dielectric layer 150 having an adsorption or clamping electrode 155, thereby forming a dielectric stack structure 10. The heater dielectric layer 140 may be combined with the electrostatic dielectric layer 150 by a thermal coupling process using heat and pressure. The thermal coupling process may be performed at a temperature of about 280° C. to about 380° C. and a pressure of about 200 psi to about 700 psi. By the thermal coupling process, the heater dielectric layer 140 and the electrostatic dielectric layer 150 may be combined with each other without an adhesive layer, that is, such that an interface therebetween is free of the adhesive layer. When an adhesive layer is not used, a thickness variation of the dielectric stack structure 10 may be reduced or prevented. In other words, a thickness of the dielectric stack structure 10 may be substantially uniform.

A heat distribution layer 157 may be further provided between the heater dielectric layer 140 and the electrostatic dielectric layer 150. For example, at least one of aluminum nitride (AlN), boron nitride (BN), tungsten (W), and molybdenum (Mo) which have heat conductivities of about 10 W/mK or more may be coated or deposited on a bottom surface, which is adjacent to the heater dielectric layer 140, of the electrostatic dielectric layer 150 to form the heat distribution layer 157.

In other embodiments, the heater dielectric layer 140 and the electrostatic dielectric layer 150 may be bonded to each other by an adhesive layer having a thickness (e.g., about 100 μm) that may be negligible with respect to a thickness variation, thereby forming the dielectric stack structure 10.

Referring to FIG. 5B, a metal plate 120 may be adhered to the heater dielectric layer 140 by a first adhesive 131 interposed therebetween. The first adhesive 131 may have a low heat conductivity. For example, the first adhesive 131 may include at least one of silicon, acryl, epoxy, or polyimide. The metal plate 120 may be formed of, for example, copper (Cu), aluminum (Al), or any alloy thereof. For example, the metal plate 120 may have a disk shape of which a size (e.g., a diameter) is substantially equal to or similar to that of the heater dielectric layer 140. After the metal plate 120 is adhered, the first adhesive 131 may be hardened.

Referring to FIG. 5C, the dielectric stack structure 10 to which the metal plate 120 is adhered may be attached to the base 110 using a second adhesive 132. The second adhesive 132 may be provided on the base 110. In other embodiments, the second adhesive 132 may be provided on the metal plate 120. Like the first adhesive 132, the second adhesive 132 may have a low heat conductivity. For example, the second adhesive 132 may include at least one of silicon, acryl, epoxy, or polyimide. A thickness of the second adhesive 132 may be greater than that of the first adhesive 131. For example, the first adhesive 131 may have the thickness of about 100 μm, and the second adhesive 132 may have the thickness of about 1000 μm. A surface 132s of the second adhesive 132 may be non-flat or non-planar, so the second adhesive 132 may have a non-uniform thickness.

Referring to FIG. 5D, pressure may be applied to the dielectric stack structure 10 toward the base 110, and thus, the second adhesive 132 may be pressed by the metal plate 120. When the pressure is applied, the dielectric stack structure 10 and the metal plate 120 may be kept horizontal or even with the base 110. Owing to the applied pressure, the second adhesive 132 may be pressed by the metal plate 120. Since the second adhesive 132 is pressed by the meal plate 120 in the state that the dielectric stack structure 10 and the metal plate 120 are is horizontal, the thickness of the second adhesive 132 may become substantially uniform. For example, the second adhesive 132 may have a reduced thickness of about 900 μm or less from the initial thickness of about 1000 μm, and the surface 132s of the second adhesive 132 may become flat or planar. After the pressure is applied, heat may be provided to harden the second adhesive 132. Alternatively, the pressure and heat may be provided overlapping or at the same time, so the second adhesive 132 may be hardened while pressure is applied by the metal plate 120. In other embodiments, a top surface, to be adhered to the metal plate 120, of the base 110 may be planarized before the dielectric stack structure 10 is adhered to the base 110.

Referring to FIG. 5E, an electrostatic chuck 101 may be fabricated by the processes described above. The electrostatic chuck 101 may include the base 110 and the dielectric stack structure 10 combined with the base 110 by an adhesive layer 130 having a double-layered structure consisting of the first and second adhesives 131 and 132. The first adhesive 131 may be adjacent to the heater dielectric layer 140, and the second adhesive 132 may be adjacent to the base 110. The metal plate 120 may be provided between the first adhesive 131 and the second adhesive 132 to make the thermal distribution uniform in the electrostatic chuck 101.

According to the present embodiment, even though the second adhesive 132 does not have a uniform thickness, the second adhesive 132 may be pressed by the metal plate 120 to result in a substantially uniform thickness when the dielectric stack structure 10 is combined with the base 110. In addition, since the thickness of the first adhesive 131 is smaller than that of the second adhesive 132, a thickness variation caused by the first adhesive 131 negligible or may be neglected. Thus, the adhesive layer 130 may have a substantially uniform thickness.

Since the thickness of the adhesive layer 130 is substantially uniform, a distance variation between the dielectric stack structure 10 and the base 110 may be reduced or minimized or removed. Thus, the temperature sensor 114 may accurately sense the temperature of the electrostatic chuck 101 and/or the substrate 90 of FIG. 1, and the electrostatic chuck 101 and/or the substrate 90 may be uniformly cooled by the coolant flowing through the channel 112 under control of the temperature adjuster 230 and the controller 250. In other words, the temperature distribution of the electrostatic chuck 101 and/or the substrate 90 may become substantially uniform.

Since the second adhesive 132 may be thicker than the first adhesive 131, heat loss from the dielectric stack structure 10 to the base 110 may be reduced. In other embodiments, the thickness of the second adhesive 132 may be substantially equal to, similar to or less than that of the first adhesive 131.

In still other embodiments, each of the first and second adhesives 131 and 132 may be formed of a high-heat-conductive material that includes a matrix (e.g., silicon, acryl, epoxy, or polyimide) and heat-conductive fillers (e.g., metal particles) included in the matrix. The thermal or heat conductivity of the second adhesive 132 may be smaller than that of the first adhesive 131. For example, the heat-conductive fillers may form a continuous network in the matrix of the first adhesive 131, so the first adhesive 131 may have a relatively greater heat conductivity. On the other hand, the heat-conductive fillers may form a discontinuous network in the matrix of the second adhesive 132, so the second adhesive 132 may have a relatively smaller heat conductivity.

In this case, since the heat conductivity of the first adhesive 131 is greater than that of the second adhesive 132, the heat may be more uniformly transmitted along a planar direction of the first adhesive 131 as well as a thickness direction of the first adhesive 131. Thus, the thermal distribution of the metal plate 120 may become more uniform. Since the heat conductivity of the second adhesive 132 is smaller than that of the first adhesive 131, heat loss from the adhesive layer 130 may be suppressed. Thus, the thermal distribution of the metal plate 120 may become more uniform. The second adhesive 132 may be thicker than the first adhesive 131, thereby reducing or minimizing the heat loss. Alternatively, in other embodiments, the thickness of the second adhesive 132 may be substantially equal to, similar to or less than that of the first adhesive 131.

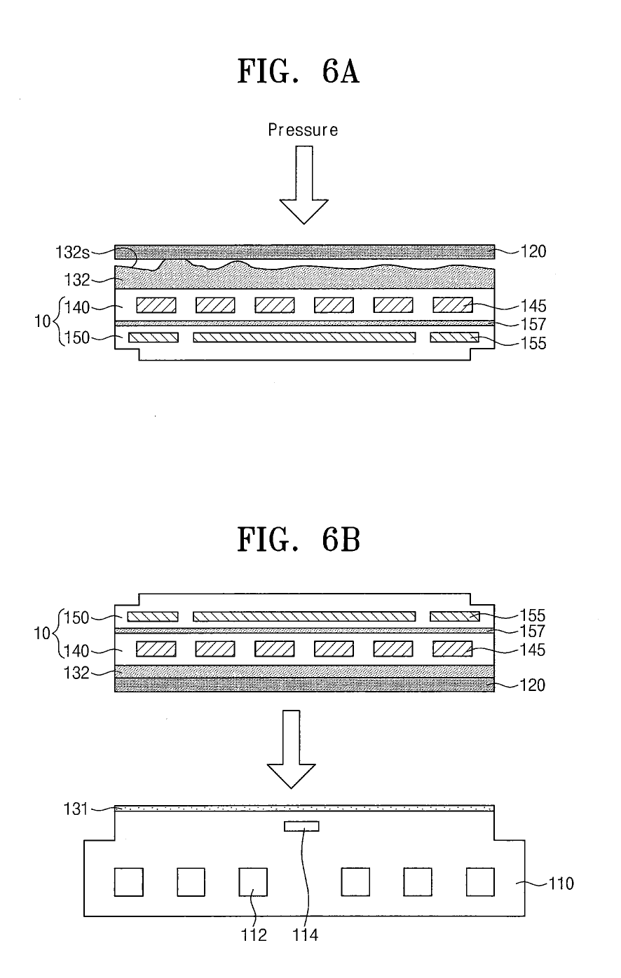

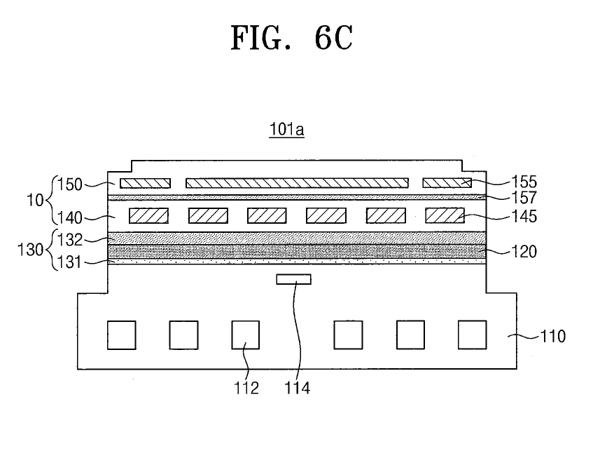

FIGS. 6A to 6C are cross-sectional views illustrating methods of forming an electrostatic chuck according to other embodiments of the inventive concepts.

Referring to FIG. 6A, the heater dielectric layer 140 may be combined with the electrostatic dielectric layer 150 by the thermal coupling process described with reference to FIG. 5A, thereby forming the dielectric stack structure 10. The heat distribution layer 157 may be further provided between the heater dielectric layer 140 and the electrostatic dielectric layer 150. The second adhesive 132 may be coated on the heater dielectric layer 140, and the metal plate 120 may be provided on the second adhesive 132. The second adhesive 132 may have a relatively greater thickness (e.g., about 1000 μm) and the uneven or non-planar surface 132s. Pressure may be applied to the metal plate 120 to reduce or remove a thickness variation of the second adhesive 132. The metal plate 120 may press the second adhesive 132 by the pressure, and thus, the second adhesive 132 may have a substantially uniform thickness. Heat may be applied to harden the second adhesive 132. In other embodiments, the heat and the pressure may be provided overlapping or at the same time, so the second adhesive 132 may be hardened while being pressed by the metal plate 120.

Referring to FIG. 6B, the dielectric stack structure 10 to which the metal plate 120 is adhered may be attached to the base 110 by means of the first adhesive 131. The first adhesive 131 may be provided on the base 110. In other embodiments, the first adhesive 131 may be provided on the metal plate 120. Heat may be applied to harden the first adhesive 131 in the state that the dielectric stack structure 10 is attached to the base 110.

Referring to FIG. 6C, an electrostatic chuck 101a may be fabricated by the processes described above. The electrostatic chuck 101a may include the base 110 and the dielectric stack structure 10 combined with the base 110 by the adhesive layer 130 having the double-layered structure consisting of the first and second adhesives 131 and 132. In addition, the electrostatic chuck 101a may further include the metal plate 120 provided between the first and second adhesives 131 and 132. The first adhesive 131 may be adjacent to the base 110, and the second adhesive 132 may be adjacent to the heater dielectric layer 140. Thicknesses and heat conductivities of the first and second adhesives 131 and 132 may be substantially equal to or similar to those of the first and second adhesives 131 and 132 described with reference to FIGS. 5A to 5E. In the following embodiments, thicknesses and heat conductivities of first and second adhesives may be substantially equal to or similar to those of the first and second adhesives 131 and 132 described with reference to FIGS. 5A to 5E.

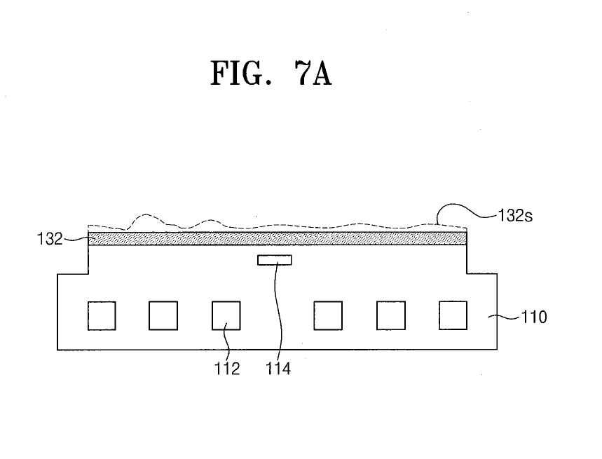

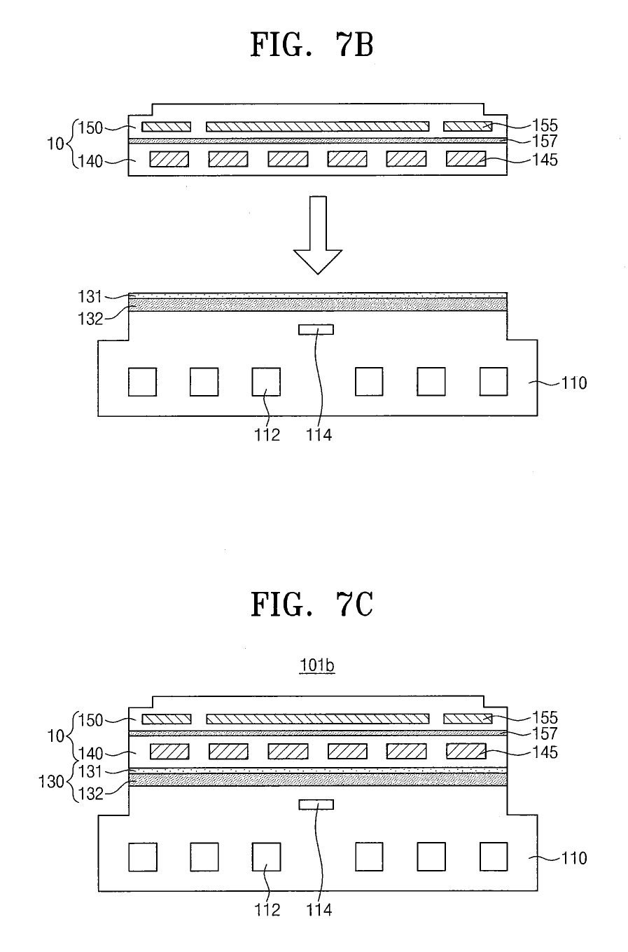

FIGS. 7A to 7C are cross-sectional views illustrating methods of forming an electrostatic chuck according to still other embodiments of the inventive concepts.

Referring to FIG. 7A, the second adhesive 132 may be coated on the base 110. The second adhesive 132 may have a relatively greater thickness (e.g., about 1000 μm) and the uneven or non-planar surface 132s. After heat may be applied to harden the second adhesive 132, the surface 132s may be planarized by a mechanical process. Thus, it is possible to obtain the second adhesive 132 which is hardened and has the flatness secured by the mechanical process. The hardened second adhesive 132 may have a thickness of about 900 μm or less.

Referring to FIG. 7B, the dielectric stack structure 10 may be adhered to the base by means of the first adhesive 131. The first adhesive 131 may be provided on the second adhesive 132 or the heater dielectric layer 140. A thickness (e.g., about 100 μm) of the first adhesive 131 may be smaller than that of the second adhesive 132, so a thickness variation caused by the first adhesive 131 may be negligible or disregarded. The dielectric stack structure 10 may be bonded and formed by the thermal coupling process described with reference to FIG. 5A.

Referring to FIG. 7C, the first adhesive 131 may be hardened by heat, thereby providing an electrostatic chuck 101b. The electrostatic chuck 101b may include the base 110 and the dielectric stack structure 10 combined with the base 110 by the adhesive layer 130 of the double-layered structure consisting of the first and second adhesives 131 and 132. The first adhesive 131 may be adjacent to the heater dielectric layer 140, and the second adhesive 132 may be adjacent to the base 110. According to the present embodiment, since the second adhesive 132 is planarized by the mechanical process, a thickness variation of the adhesive layer 130 may be reduced or minimized or removed.

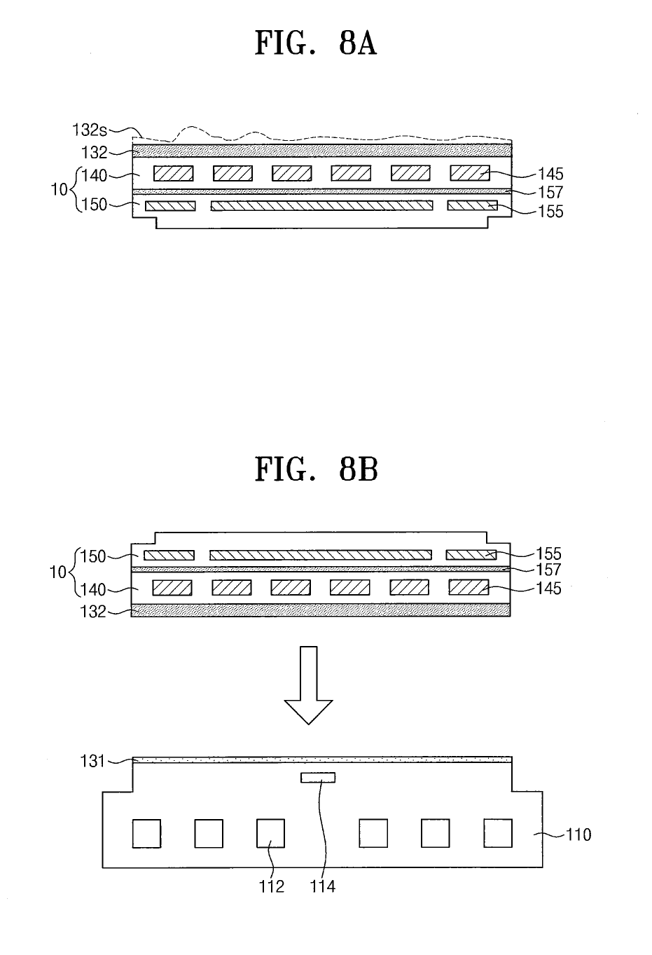

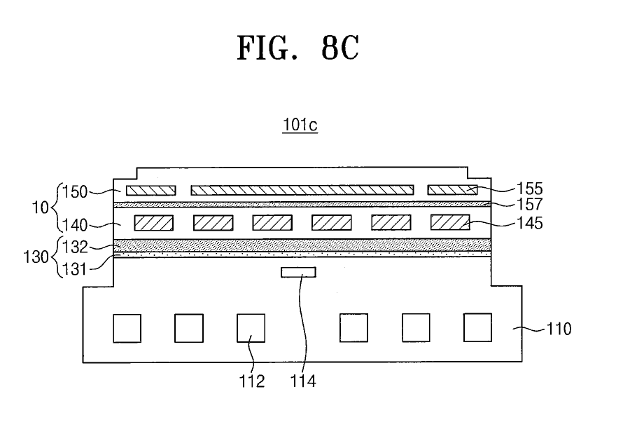

FIGS. 8A to 8C are cross-sectional views illustrating methods of forming an electrostatic chuck according to yet other embodiments of the inventive concepts.

Referring to FIG. 8A, the heater dielectric layer 140 may be combined with the electrostatic dielectric layer 150 by the thermal coupling process described with reference to FIG. 5A, thereby forming the dielectric stack structure 10. The heat distribution layer 157 may be further provided between the heater dielectric layer 140 and the electrostatic dielectric layer 150. The second adhesive 132 may be coated on the heater dielectric layer 140. The second adhesive 132 may have the uneven or non-planar surface 132s. Thus, the second adhesive 132 may be hardened by heat, and flatness of the second adhesive 132 may be secured by performing a mechanical process on the surfaces 132s.

Referring to FIG. 8B, the dielectric stack structure 10 may be adhered to the base by means of the first adhesive 131. The first adhesive 131 may be provided on the base 110. In other embodiments, the first adhesive 131 may be provided on the second adhesive 132. Heat may be applied to harden the first adhesive 131 in the state that the dielectric stack structure 10 is adhered to the base 110.

Referring to FIG. 8C, an electrostatic chuck 101c may be fabricated by the processes described above. The electrostatic chuck 101c may include the base 110 and the dielectric stack structure 10 combined with the base 110 by the adhesive layer 130 of the double-layered structure consisting of the first and second adhesives 131 and 132. The first adhesive 131 may be adjacent to the base 110, and the second adhesive 132 may be adjacent to the heater dielectric layer 140.

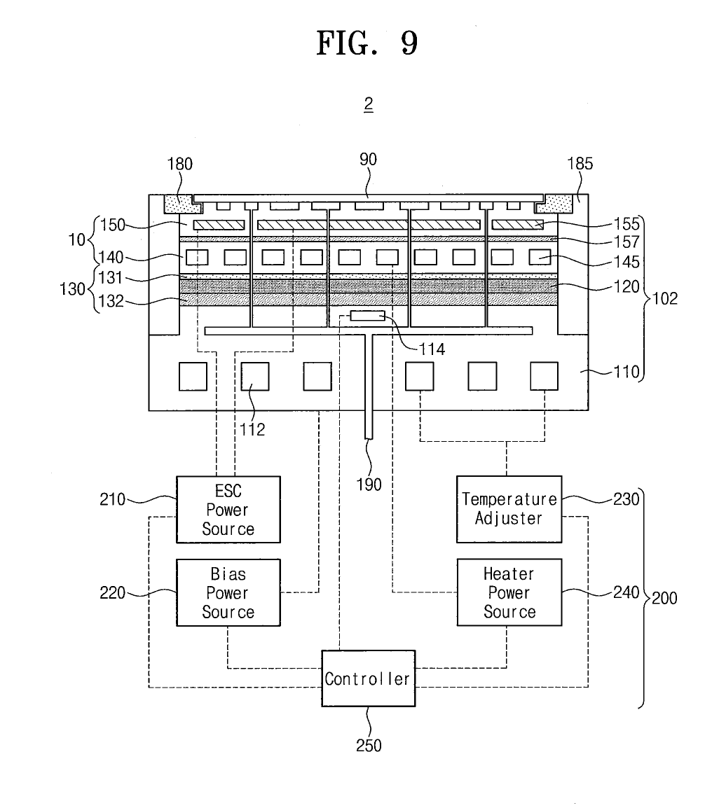

FIG. 9 is a cross-sectional view illustrating an electrostatic chuck assembly or apparatus according to other embodiments of the inventive concepts.

Referring to FIG. 9, an electrostatic chuck assembly or apparatus 2 may include an electrostatic chuck 102 configured to adsorb or clamp a substrate 90 to a surface thereof using electrostatic force, and a control part 200 controlling operation of the electrostatic chuck 102. Hereinafter, differences between the electrostatic chuck assembly 2 and the electrostatic chuck assembly 1 of FIG. 1 will be mainly described, and the descriptions of the same elements as mentioned in FIG. 1 will be omitted or described briefly.

The electrostatic chuck 102 may include a disk-shaped base 110 including a channel 112 and a temperature sensor 114, a dielectric stack structure 10 adhered to the base 110 by an adhesive layer 130 interposed therebetween, and a focus ring 180 having a ring shape extending along an edge of the substrate 90. An outer ring 185 may be further provided to shield an outer sidewall of the electrostatic chuck 102.

The dielectric stack structure 10 may include a heater dielectric layer 140 and an electrostatic dielectric layer 150. The heater dielectric layer 140 may have a disk shape in which a heater electrode 145 is embedded. The electrostatic dielectric layer 150 may have a disk shape in which an adsorption or clamping electrode 155 is embedded. A heat distribution layer 157 may be further provided between the heater dielectric layer 140 and the electrostatic dielectric layer 150. The adhesive layer 130 may have a double-layered structure including a first adhesive 131 and a second adhesive 132. A metal plate 120 may be further provided between the first adhesive 131 and the second adhesive 132.

The control part 200 may include an ESC power source 210 providing a power to the adsorption or clamping electrode 155, a bias power source 220 providing a bias power to the base 110, a temperature adjuster 230 adjusting a flow and a temperature of a coolant flowing through the channel 112, a heater power source 240 providing a power to the heater electrode 145, and a controller 250 controlling the temperature adjuster 230 and the power sources 210, 220, and 240.

The electrostatic chuck 102 may further include a channel 190 that penetrates the electrostatic chuck 102 to provide a heat-conductive gas to the substrate 90. Since a temperature of the substrate 90 is adjusted by proving the heat-conductive gas, damages to the substrate 90 may be reduced and a uniform plasma treatment may be realized. The heat-conductive gas may be an inert gas such as helium (He) or argon (Ar). The channel 190 may be formed by a mechanical process such as a drilling process.

A patterning process of reproducibly forming the heater electrode 145, a thermal coupling process of combining the electrostatic dielectric layer 150 with the heater dielectric layer 140, and a process of forming the adhesive layer 130 having the double-layered structure may be the same as described above, so the descriptions thereto will be omitted.

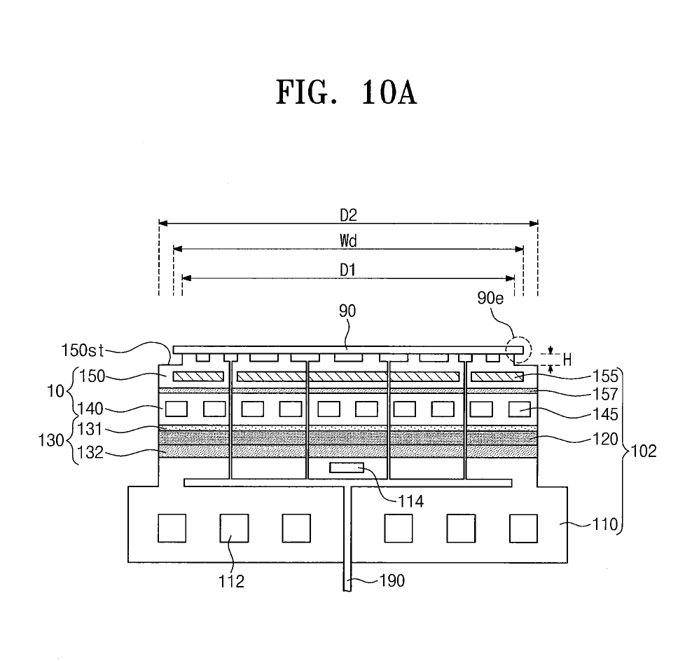

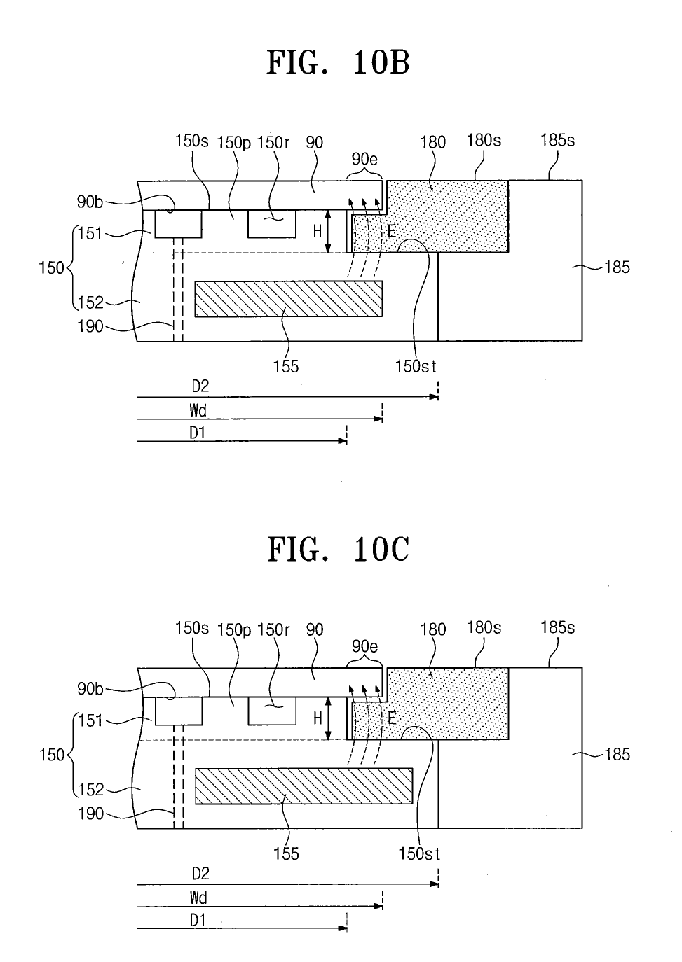

FIG. 10A is a cross-sectional view of a portion of FIG. 9. FIG. 10B is an enlarged cross-sectional view of a portion of FIG. 10A. FIG. 10C is a cross-sectional view illustrating a modified embodiment of FIG. 10B.

Referring to FIGS. 10A and 10B, the electrostatic dielectric layer 150 may include a step pattern 150st which is formed by recessing an upper sidewall of the electrostatic dielectric layer 150. The step pattern 150st may have a height H of about 0.5 mm to about 4 mm. Since the step pattern 150st is formed, the electrostatic dielectric layer 150 may include an upper portion 151 having a first diameter D1 (e.g., in a range of about 296 mm to about 299 mm) smaller than a diameter Wd (e.g., about 300 mm) of the substrate 90 and a lower portion 152 having a second diameter D2 (e.g., in a range of about 297 mm to about 340 mm) greater than the first diameter D1. The lower portion 152 may protrude laterally from a sidewall of the upper portion 151. An edge 90e of the substrate 90 may protrude laterally from the sidewall of the upper portion 151, and the adsorption or clamping electrode 155 may also protrude laterally from the sidewall of the upper portion 151. Thus, an electric field E may be more easily applied to the edge 90e of the substrate 90. The edge of the adsorption or clamping electrode 155 may substantially overlap with the edge 90e of the substrate 90, as shown in FIG. 10B. Alternatively, as shown in FIG. 10C, the edge of the adsorption or clamping electrode 155 may extend toward the sidewall of the lower portion 152 beyond the edge 90e of the substrate 90.

A surface 180s of the focus ring 180 and/or a surface 185s of the outer ring 185 may be an even surface having a surface roughness (Ra) of about 0.8 μm or less. A surface 150s of the electrostatic dielectric layer 150 may be an uneven surface.

In some embodiments, the surface 150s of the electrostatic dielectric layer 150 may have an uneven structure that has one or more protrusions 150p and one or more recesses or recessions 150r. The protrusion 150p may have a top surface that comes in contact with the substrate 90, and the recession 150r may have a bottom surface that does not come in contact with the substrate 90. The channel 190 may be opened toward the recession 150r, so the recession 150r may be filled with the heat-conductive gas. The heat-conductive gas filled in the recession 150r may come in contact with a bottom surface 90b of the substrate 90 to deprive the substrate 90 of heat or to transmit heat to the substrate 90 that is, to conduct heat to or way from the substrate 90.

A contact area between the bottom surface 90b of the substrate 90 and the protrusions 150p may be substantially equal to or less than half an area of the bottom surface 90b of the substrate 90. In some embodiments, the contact area between the bottom surface 90b of the substrate 90 and the protrusions 150p may be in a range of about 1/100 to about 30/100 of the area of the bottom surface 90b of the substrate 90.

The top surfaces of the protrusions 150p may be disposed at the same level, and heights of the protrusions 150p may be substantially equal to or different from each other. Depths of the recessions 150r may be substantially equal to or different from each other. In some embodiments, the bottom surfaces of the recessions 150r may be disposed at the same level. Alternatively, one of the bottom surfaces of the recessions 150r may be lower than another of the bottom surfaces of the recessions 150r. Distances between the protrusions 150p and/or distances between the recessions 150r may be substantially equal to or different from each other. As described above, the arrangements and shapes of the protrusions 150p and the recessions 150r may be variously modified. These will be described in detail hereinafter.

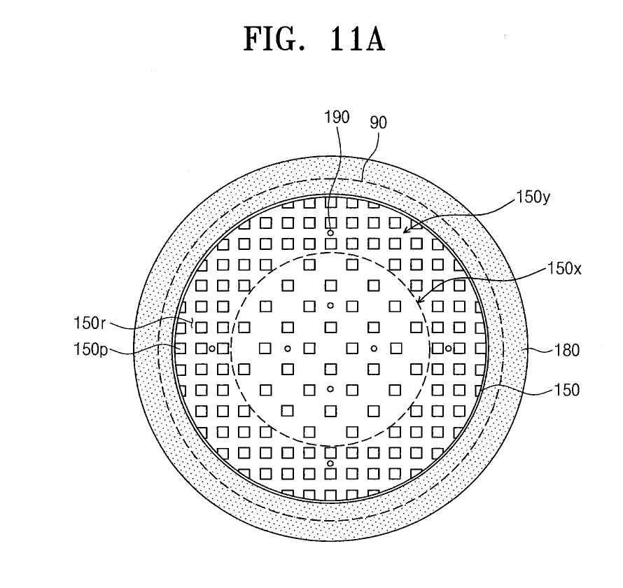

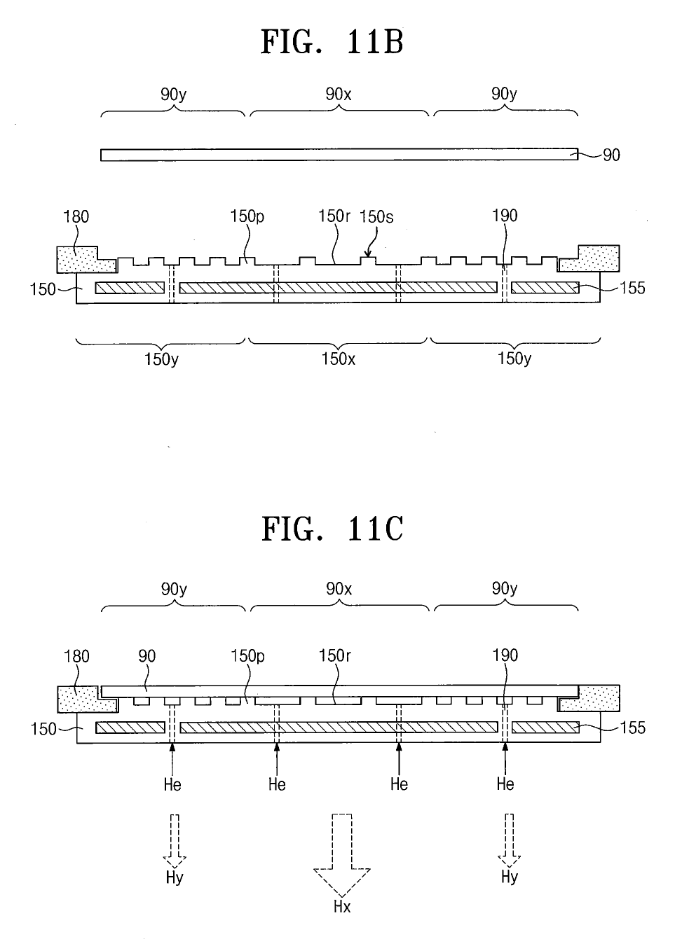

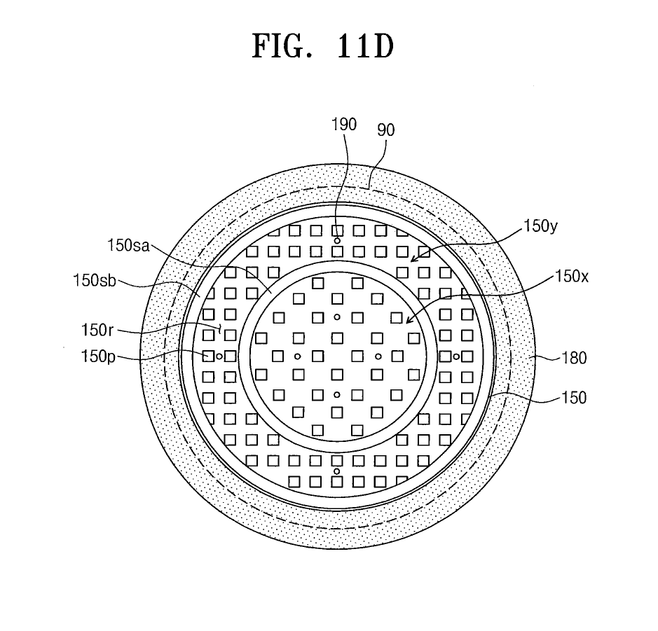

FIG. 11A is a plan view illustrating an electrostatic dielectric layer according to some embodiments of the inventive concepts. FIGS. 11B and 11C are cross-sectional views of FIG. 11A. FIG. 11D is a plan view illustrating a modified embodiment of FIG. 11A.

Referring to FIGS. 11A and 11B, the substrate 90 may include a central region 90x and an edge region 90y surrounding the central region 90x. The surface 150s of the electrostatic dielectric layer 150 may have a structure configured to or capable of raising a heat transfer rate of the central region 90x of the substrate 90 to be higher than a heat transfer rate of the edge region 90y of the substrate 90.

The electrostatic dielectric layer 150 may include an outer region 150y corresponding to the edge region 90y of the substrate 90 and an inner region 150x corresponding to the central region 90x of the substrate 90. For example, the protrusions 150p disposed in the outer region 150y of the electrostatic dielectric layer 150 may be denser than the protrusions 150p disposed in the inner region 150x of the electrostatic dielectric layer 150. In other words, a density of the protrusions 150p disposed in the outer region 150y may be higher than that of the protrusions 150p disposed in the inner region 150x. Heights of the protrusions 150p may be substantially equal to each other. Similarly, depths of the recessions 150r may be substantially equal to each other. A distance between the protrusions 150p adjacent to each other in the inner region 150x may be greater than a distance between the protrusions 150p adjacent to each other in the outer region 150y. The distance between the adjacent protrusions 150p may mean a width of the recession 150r.

According to the present embodiment, a contact area between the surface 150s of the electrostatic dielectric layer 150 and the central region 90x of the substrate 90 may be smaller than a contact area between the surface 150s of the electrostatic dielectric layer 150 and the edge region 90y of the substrate 90. In other words, a total area of the recessions 150r disposed in the inner region 150x may be greater than that of the recessions 150r disposed in the outer region 150y.

Referring to FIG. 11C, the heat-conductive gas (e.g., He) may be transmitted through the channel 190 to fill the recessions 150r. A contact area between the central region 90x of the substrate 90 and the heat-conductive gas filling the recessions 150r may be greater than a contact area between the edge region 90y of the substrate 90 and the heat-conductive gas filling the recessions 150r. As a result, a thermal or heat conductivity Hx of the central region 90x of the substrate 90 may be greater than a thermal or heat conductivity Hy of the edge region 90y of the substrate 90. The electrostatic dielectric layer 150 according to the present embodiment may be useful when a temperature of the central region 90x of the substrate 90 is higher than that of the edge region 90y of the substrate 90. In addition, the electrostatic dielectric layer 150 of the present embodiment may also be useful if when is necessary or desired to effectively or rapidly reduce the temperature of the central region 90x of the substrate 90.

Referring to FIG. 11D, the electrostatic dielectric layer 150 may further include a plurality of ring-shaped supporting portions. For example, the electrostatic dielectric layer 150 may further include an inner supporting portion 150sa having a ring shape and an outer supporting portion 150sb having a ring shape continuously extending along a circumference of the electrostatic dielectric layer 150. Heights of the inner supporting portion 150sa and the outer supporting portion 150sb may be substantially equal to that of the protrusion 150p. A region surrounded by the inner supporting portion 150sa may correspond to the inner region 150x of the electrostatic dielectric layer 150, and a region between the inner and outer supporting portions 150sa and 150sb may correspond to the outer region 150y of the electrostatic dielectric layer 150.

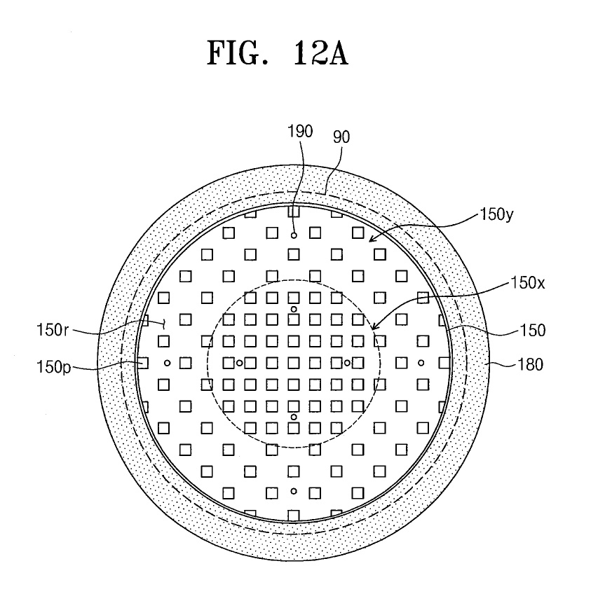

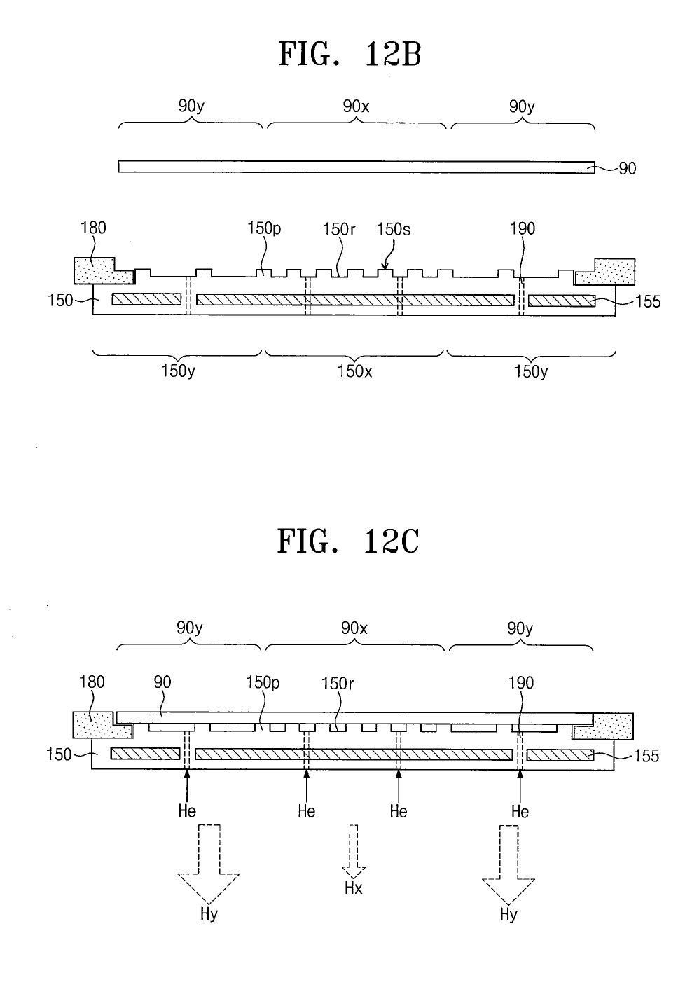

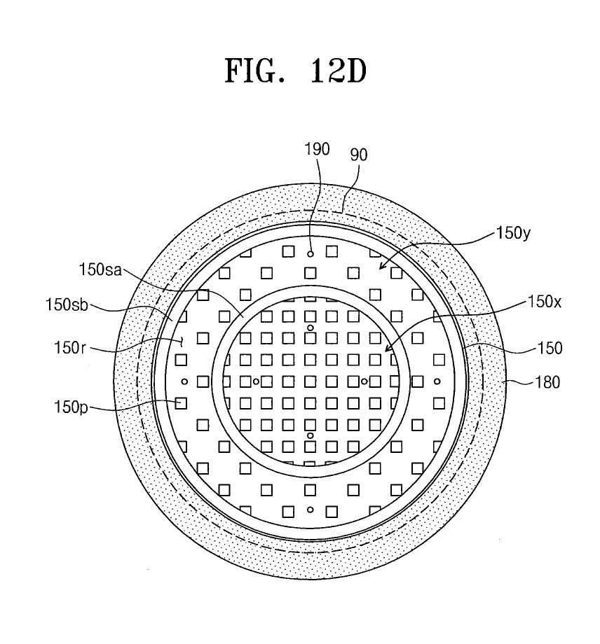

FIG. 12A is a plan view illustrating an electrostatic dielectric layer according to other embodiments of the inventive concepts. FIGS. 12B and 12C are cross-sectional views of FIG. 12A. FIG. 12D is a plan view illustrating a modified embodiment of FIG. 12A.

Referring to FIGS. 12A and 12B, the surface 150s of the electrostatic dielectric layer 150 may have a structure configured for or capable of raising a heat transfer rate of the edge region 90y of the substrate 90 to be higher than a heat transfer rate of the central region 90x of the substrate 90.

For example, the protrusions 150p disposed in the inner region 150x of the electrostatic dielectric layer 150 may be denser than the protrusions 150p disposed in the outer region 150x of the electrostatic dielectric layer 150. Heights of the protrusions 150p may be substantially equal to each other. Similarly, depths of the recesses or recessions 150r may be substantially equal to each other. A distance between the protrusions 150p adjacent to each other in the outer region 150y may be greater than a distance between the protrusions 150p adjacent to each other in the inner region 150x.

According to the present embodiment, a contact area between the surface 150s of the electrostatic dielectric layer 150 and the edge region 90y of the substrate may be smaller than a contact area between the surface 150s of the electrostatic dielectric layer 150 and the central region 90x of the substrate 90. In other words, a total area of the recessions 150r disposed in the outer region 150y may be greater than that of the recessions 150r disposed in the inner region 150x.

Referring to FIG. 12C, the heat-conductive gas (e.g., helium He) may be transmitted through the channel 190 to fill the recessions 150r. A contact area between the edge region 90y of the substrate 90 and the heat-conductive gas filling the recessions 150r may be greater than a contact area between the central region 90x of the substrate 90 and the heat-conductive gas filling the recessions 150r. As a result, the heat conductivity Hy of the edge region 90y of the substrate 90 may be greater than the heat conductivity Hx of the central region 90x of the substrate 90. The electrostatic dielectric layer 150 according to the present embodiment may be useful when a temperature of the edge region 90y of the substrate 90 is higher than that of the central region 90x of the substrate 90. In addition, the electrostatic dielectric layer 150 of the present embodiment may also be useful when it is necessary or desired to effectively or rapidly reduce the temperature of the edge region 90y of the substrate 90.

Referring to FIG. 12D, the electrostatic dielectric layer 150 may further include the inner supporting portion 150sa and the outer supporting portion 150sb that are the same as or similar to those illustrated in FIG. 11D. The inner region 150x may correspond to a region surrounded by the inner supporting portion 150sa, and the outer region 150y may correspond to a region between the inner and outer supporting portions 150sa and 150sb.

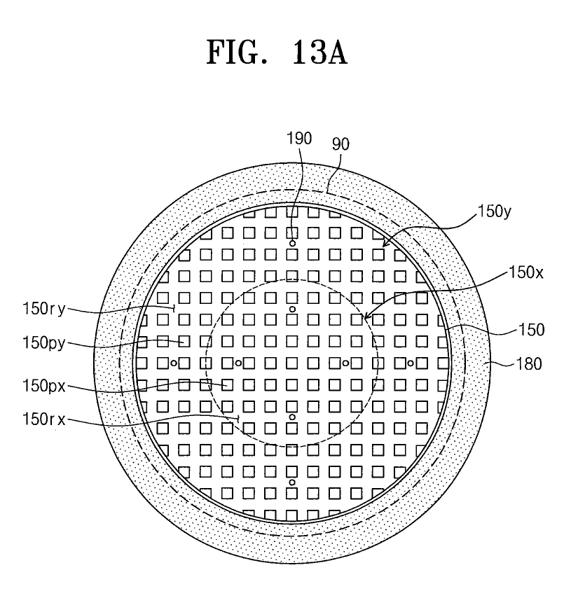

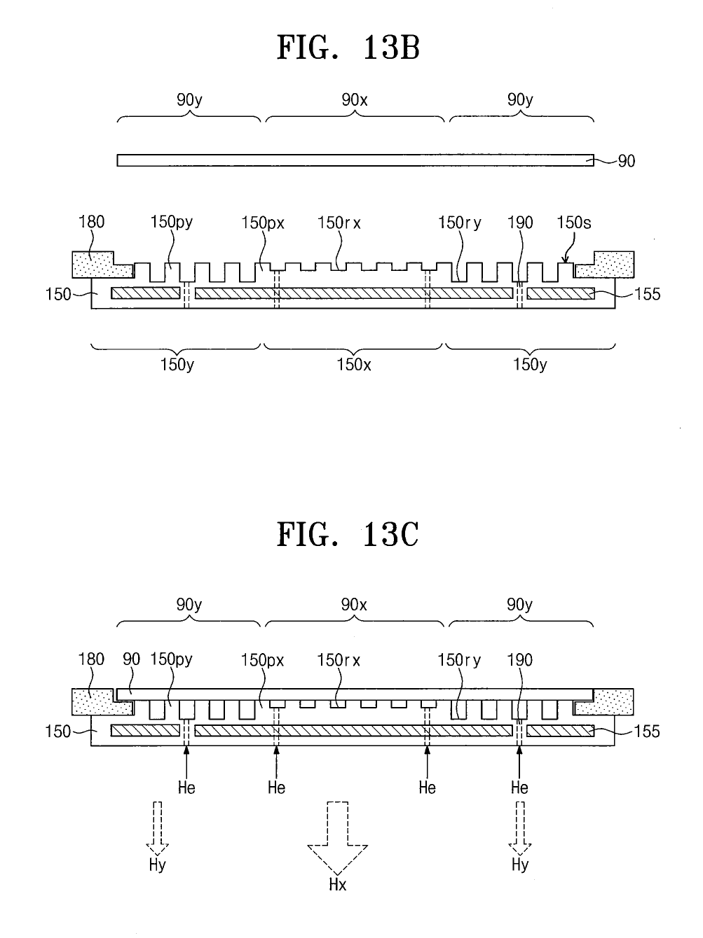

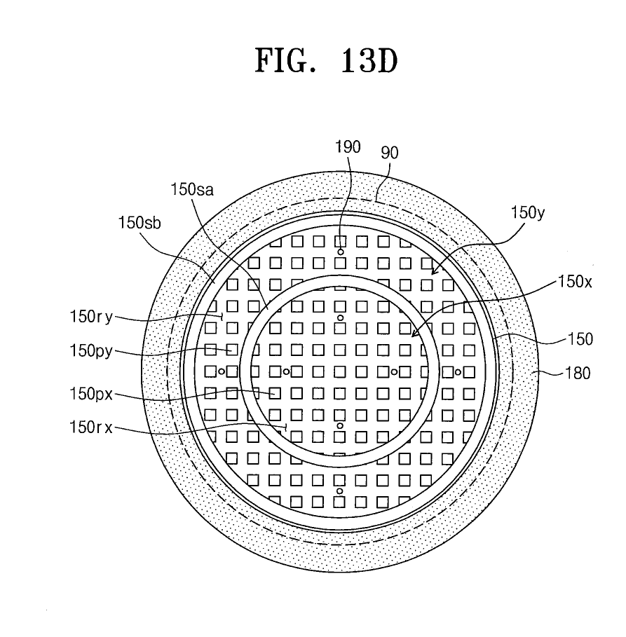

FIG. 13A is a plan view illustrating an electrostatic dielectric layer according to still other embodiments of the inventive concepts. FIGS. 13B and 13C are cross-sectional views of FIG. 13A. FIG. 13D is a plan view illustrating a modified embodiment of FIG. 13A.

Referring to FIGS. 13A and 13B, the surface 150s of the electrostatic dielectric layer 150 may have a structure configured to or capable of raising a heat transfer rate of the central region 90x of the substrate 90 to be higher than a heat transfer rate of the edge region 90y of the substrate 90.

For example, inner protrusions 150px disposed in the inner region 150x of the electrostatic dielectric layer 150 may have a smaller height, and outer protrusions 150py disposed in the outer region 150y of the electrostatic dielectric layer 150 may have a greater height. In other words, an inner recess or recession 150rx disposed in the inner region 150x may have a smaller depth, and an outer recess or recession 150ry disposed in the outer region 150y may have a greater depth. A density of the inner protrusions 150px may be substantially equal to or similar to that of the outer protrusions 150py.

Referring to FIG. 13C, a contact area between the heat-conductive gas (e.g., helium He) filling the inner recession 150rx and the central region 90x of the substrate 90 may be substantially equal to or similar to a contact area between the heat-conductive gas filling the outer recession 150ry and the edge region 90y of the substrate 90. A volume of the heat-conductive gas filling the inner recession 150rx may be smaller than a volume of the heat-conductive gas filling the outer recession 150ry, so a heat conductivity Hx of the central region 90x of the substrate 90 may be greater than a heat conductivity Hy of the edge region 90y of the substrate 90. Like the embodiment illustrated in FIG. 11C, the electrostatic dielectric layer 150 according to the present embodiment may be useful when a temperature of the central region 90x of the substrate 90 is higher than that of the edge region 90y of the substrate 90 and/or when it is necessary or desired to effectively or rapidly reduce the temperature of the central region 90x of the substrate 90.

Referring to FIG. 13D, the electrostatic dielectric layer 150 may further include the inner supporting portion 150sa and the outer supporting portion 150sb that are the same as or similar to those illustrated in FIG. 11D. Like FIG. 11D, the inner region 150x may correspond to a region surrounded by the inner supporting portion 150sa, and the outer region 150y may correspond to a region between the inner and outer supporting portions 150sa and 150sb.

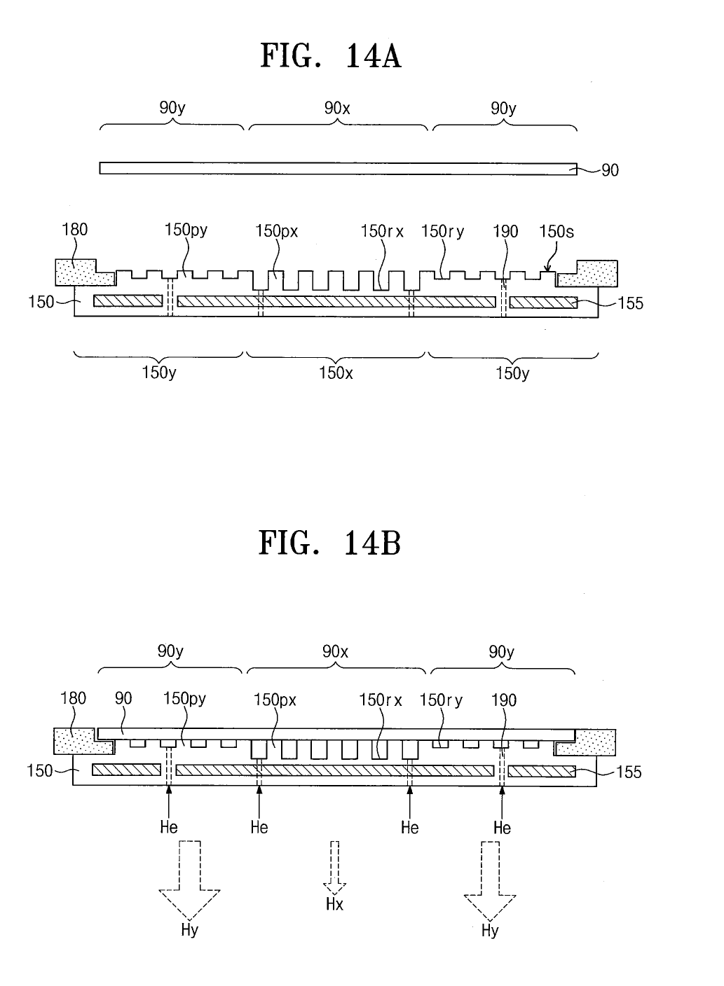

FIGS. 14A and 14B are cross-sectional views illustrating an electrostatic dielectric layer according to yet other embodiments of the inventive concepts.

Referring to FIG. 14A, the surface 150s of the electrostatic dielectric layer 150 may have a structure configured for or capable of raising a heat transfer rate of the edge region 90y of the substrate 90 to be higher than a heat transfer rate of the central region 90x of the substrate 90. The electrostatic dielectric layer 150 may have the same planar structure as illustrated in FIG. 13A or 13D.

For example, the outer protrusions 150py may have a smaller height, and the inner protrusions 150px may have a greater height. In other words, the outer recess or recession 150ry may have a smaller depth, and the inner recess or recession 150rx may have a greater depth. A density of the inner protrusions 150px may be substantially equal to or similar to that of the outer protrusions 150py.

Referring to FIG. 14B, a contact area between the heat-conductive gas (e.g., helium He) filling the inner recession 150rx and the central region 90x of the substrate 90 may be substantially equal to or similar to a contact area between the heat-conductive gas filling the outer recession 150ry and the edge region 90y of the substrate 90. A volume of the heat-conductive gas filling the outer recession 150ry may be smaller than a volume of the heat-conductive gas filling the inner recession 150rx, so a heat conductivity Hy of the edge region 90y of the substrate 90 may be greater than a heat conductivity Hx of the central region 90x of the substrate 90. Like the embodiment illustrated in FIG. 12C, the electrostatic dielectric layer 150 according to the present embodiment may be useful when a temperature of the edge region 90y of the substrate 90 is higher than that of the central region 90x of the substrate 90 and/or when it is necessary or desired to effectively or rapidly reduce the temperature of the edge region 90y of the substrate 90.

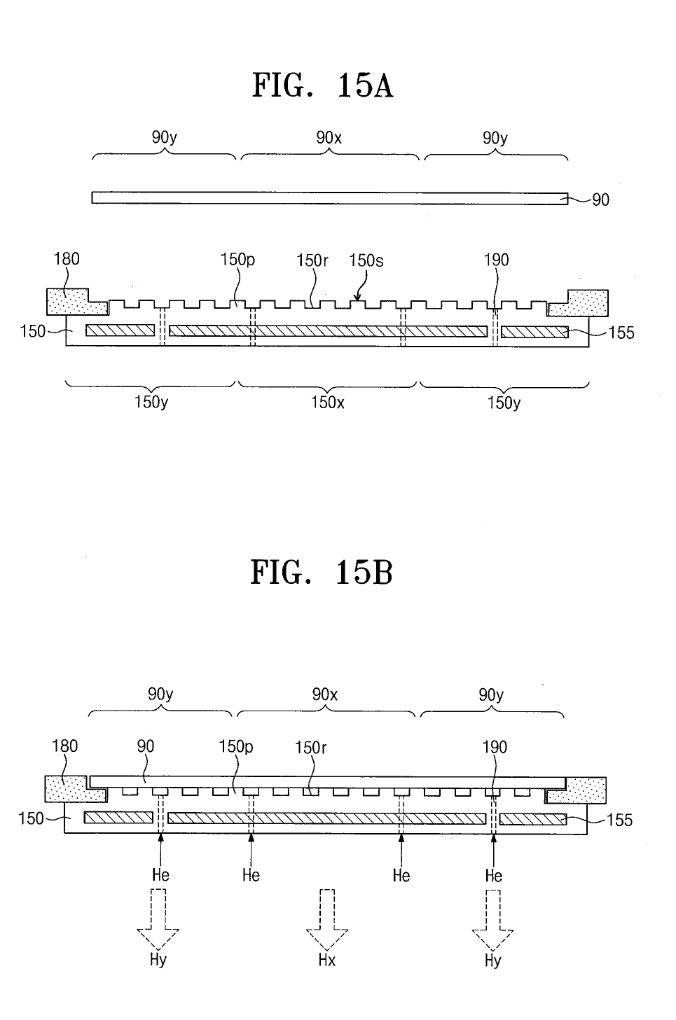

FIGS. 15A and 15B are cross-sectional views illustrating an electrostatic dielectric layer according to yet still other embodiments of the inventive concepts.

Referring to FIG. 15A, the surface 150s of the electrostatic dielectric layer 150 may have a structure configured for or capable of making a heat transfer rate of the central region 90x of the substrate 90 substantially equal or similar to a heat transfer rate of the edge region 90y of the substrate. For example, the protrusions 150p may have the same height and may be arranged at equal distances. The recesses or recessions 150r may have the same depth and same distances. The electrostatic dielectric layer 150 may have the same planar structure as illustrated in FIG. 13A or 13D.

Referring to FIG. 15B, a contact area between the heat-conductive gas (e.g., helium He) filling the recession 150r of the inner region 150x and the central region 90x of the substrate 90 may be substantially equal to or similar to a contact area between the heat-conductive gas filling the recession 150r of the outer region 150y and the edge region 90y of the substrate 90. A volume of the heat-conductive gas filling the recession 150r of the inner region 150x may be substantially equal to or similar to a volume of the heat-conductive gas filling the recession 150r of the outer region 150y. Thus, a heat conductivity Hy of the edge region 90y of the substrate 90 may be substantially equal to or similar to a heat conductivity Hx of the central region 90x of the substrate 90.

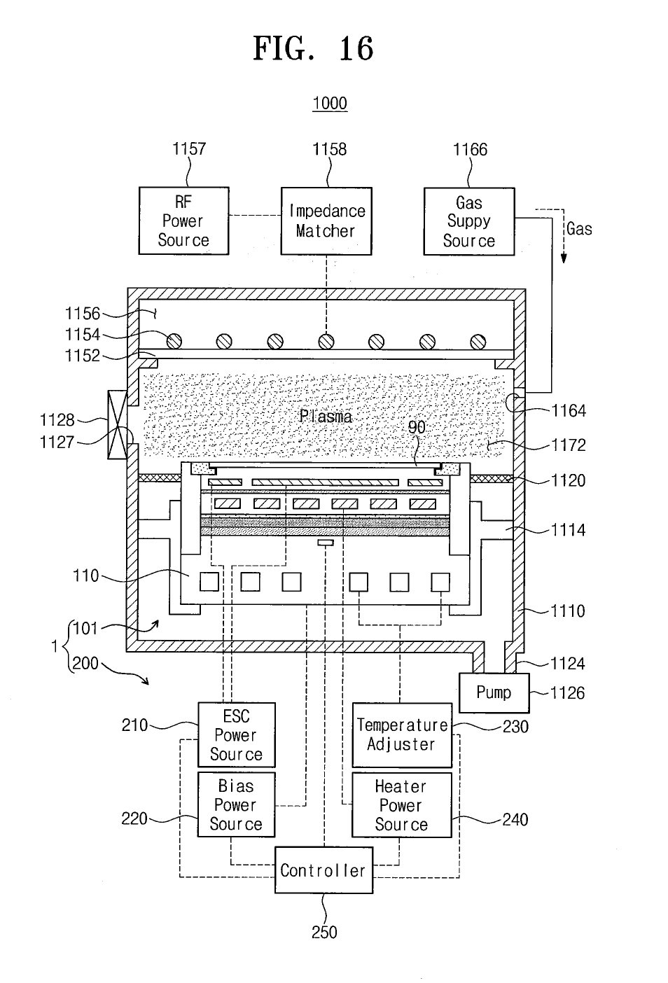

FIG. 16 is a cross-sectional view illustrating a semiconductor fabricating apparatus including an electrostatic chuck according to embodiments of the inventive concepts.

Referring to FIG. 16, a semiconductor fabricating apparatus 1000 may be an inductively coupled plasma (ICP) treatment apparatus that treats a substrate 90 mounted on the electrostatic chuck 101 by plasma generated through an inductively coupled method. In other embodiments, the electrostatic chuck 101 may also be used in an etching treatment apparatus using capacitively coupled plasma (CCP).

The semiconductor fabricating apparatus 1000 may include the electrostatic chuck assembly 1 that is disposed in a lower central region of a vacuum chamber 1110. The vacuum chamber 1110 may have a cylindrical shape and may be formed of a metal material. As described with reference to FIG. 1, the electrostatic chuck assembly 1 may include the electrostatic chuck 101 and the control part 200. The electrostatic chuck assembly 2 of FIG. 9 may be installed in the semiconductor fabricating apparatus 1000 instead of the electrostatic chuck assembly 1. The electrostatic chuck assemblies 1 and 2 were described with reference to FIGS. 1 and 9. Thus, the detail descriptions of the electrostatic chuck assemblies 1 and 2 will be omitted hereinafter.

The electrostatic chuck 101 may be supported by a supporter 1114 fixed on an inner sidewall of the chamber 1110. A baffle plate 1120 may be provided between the electrostatic chuck 101 and the inner sidewall of the chamber 1110. An exhaust pipe 1124 may be provided at a lower portion of the chamber 1110. The exhaust pipe 1124 may be connected to a vacuum pump 1126. A gate valve 1128 may be provided on an outer sidewall of the chamber 1110. The gate valve 1128 may open and close an opening 1127 through which the substrate 90 is inputted and outputted.

A dielectric window 1152 may be provided at a ceiling of the chamber 1110. The dielectric window 1152 is spaced apart from the electrostatic chuck 101. An antenna room 1156 may be disposed on the dielectric window 1152. The antenna room 1156 may receive a high-frequency or radio-frequency antenna 1154 (hereinafter, referred to as ‘a RF antenna’) having, for example, a helical or concentric coil shape. The antenna room 1157 and the chamber 1110 may be in a single unitary body. The RF antenna 1154 may be electrically connected to a high-frequency or radio-frequency (RF) power source 1157 (hereinafter, referred to as ‘a RF power source’) through an impedance matcher 1158. The RF power source 1156 may be used to generate plasma. The impedance matcher 1158 may be provided to match impedance of the RF power source 1157 with impedance of a load (e.g., the RF antenna 1154). A gas supply source 1166 may supply a treatment gas (e.g., an etching gas) into the chamber 1110 through a supply unit 1164 (e.g., a nozzle or a port hole) equipped at a sidewall of the chamber 1110.

To perform an etching treatment using the semiconductor fabricating apparatus 1000, the gate valve 1128 may be opened to input the substrate 90 into the chamber 1110 and the substrate 90 may be loaded on the electrostatic chuck 101. The substrate 90 may be adsorbed or clamped on the electrostatic chuck 101 by the electrostatic force generated by applying the power from the ESC power source 210 to the electrostatic chuck 101.

The etching gas may be supplied from the gas supply source 1166 into the chamber 1110. At this time, a pressure of the inside of the chamber 1110 may be set to a predetermined value by the vacuum pump 1126. Power may be applied from the RF power source 1157 to the RF antenna 1154 through the impedance matcher 1158. In addition, power may be applied from the bias power source 220 to the base 110.

The etching gas supplied in the chamber 1110 may be uniformly diffused in a treatment room 1172 disposed under the dielectric window 1152. A magnetic field may be generated around the RF antenna 1154 by a current flowing through the RF antenna 1154, and a line of the magnetic field may penetrate the dielectric window 1152 to pass through the treatment room 1172. An induced electric field may be generated by the temporal variation of the magnetic field, and electrons accelerated by the induced electric field may be collided with molecules or atoms of the etching gas to generate the plasma. Ions of the plasma may be supplied to the substrate 90, so the etching treatment may be performed.

Since the electrostatic chuck 101 has the step pattern 150st as described with reference to FIGS. 2A and 2B, the electric field may be uniformly applied up to an entire portion of the substrate 90. As a result, it may be possible to improve the uniformity of the plasma treatment with respect to the substrate 90.

If the electrostatic chuck assembly 2 including the electrostatic chuck 102 of FIG. 9 is equipped in the semiconductor fabricating apparatus 1000, the contact areas between the regions (e.g., the central and edge regions) of the substrate 90 and the regions (e.g., the inner and outer regions) of the electrostatic chuck 102 may be set to be different from each other and/or the contact areas between the heat-conductive gas and the regions of the substrate 90 may be set to be different from each other. Thus, the temperatures of the regions of the substrate 90 may be controlled independently of each other.

According to embodiments of the inventive concepts, the thickness variation of the adhesive layer inserted between the heater dielectric layer and the base may be reduced. In addition, since the metal plate is inserted into the adhesive layer, the temperature of the electrostatic chuck may become substantially uniform. The surface of the dielectric layer may be uneven or embossed, and the contact areas between the regions of the dielectric layer and the regions of the substrate may be different from each other. Thus, the temperatures of the regions of the substrate may be controlled independently of each other. In other words, it is possible to improve the temperature distribution of the electrostatic chuck and/or the temperature distribution of the substrate adsorbed or clamped on the electrostatic chuck.

Furthermore, the step pattern may be formed in the dielectric layer to apply the electric field having a relatively greater intensity to the edge of the substrate. Thus, the electric field may be more uniformly applied to the entire portion of the substrate, and the uniformity of the process treatment may be improved.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

1. An electrostatic chuck apparatus, comprising:
a base; and
a dielectric layer on the base, the dielectric layer comprising a support surface opposite the base and a clamping electrode laterally extending along the support surface beyond an edge thereof.

2. The apparatus of claim 1, wherein the edge of the support surface defines a stepped portion relative to a portion of the dielectric layer including the clamping electrode therein.

3. The apparatus of claim 2, wherein the dielectric layer has a disk-shape, wherein the support surface has a first diameter, and wherein the stepped portion has a second diameter greater than the first diameter.

4. The apparatus of claim 1, wherein a thickness of a portion of the dielectric layer between the support surface and the clamping electrode is about 0.5 millimeters to about 4 millimeters.

5. The apparatus of claim 1, further comprising:
a dielectric focus ring on the dielectric layer adjacent the edge of the support surface, the dielectric focus ring having a higher dielectric constant than the dielectric layer.

6. The apparatus of claim 1, wherein the dielectric layer comprises an electrostatic dielectric layer, and further comprising:
a heater dielectric layer comprising a heater electrode between the electrostatic dielectric layer and the base.

7. The apparatus of claim 6, wherein an interface between the electrostatic dielectric layer and the heater dielectric layer is free of an adhesive and/or metal layer therebetween.

8. The apparatus of claim 6, further comprising a conductive heat distribution layer extending along an interface between the electrostatic dielectric layer and the heater dielectric layer adjacent the heater electrode.

9. The apparatus of claim 8, wherein the heat distribution layer comprises an electrical resistance of about 1 kilo-ohm or more between the clamping electrode and the heater electrode.

10. The apparatus of claim 6, wherein the base includes a coolant channel therein and a temperature sensor adjacent the heater dielectric layer, and further comprising:
an adhesive layer having a substantially uniform thickness extending along an interface between the heater dielectric layer and the base.

11. The apparatus of claim 10, wherein the adhesive layer comprises a multi-layer stack including first and second adhesive layers having different thermal conductivities.

12. The apparatus of claim 11, wherein the multi-layer stack further comprises a metal plate extending between the first and second adhesive layers.

13. The apparatus of claim 1, wherein the support surface comprises a plurality of recesses therein, and further comprising:
at least one gas channel coupled to the respective recesses in the support surface and defining a passage between the dielectric layer and the base to supply a heat-conductive gas to the respective recesses.

14. The apparatus of claim 13, wherein the recesses define different volumes for the heat-conductive gas in first and second regions of the support surface such that respective thermal conductivities of the first and second regions differ.

15. The apparatus of claim 14, wherein the support surface comprises a plurality of protrusions between ones of the recesses, and wherein the protrusions and recesses in the support surface have different heights, spacings, and/or depths defining the different volumes in the first and second regions thereof.

16. The apparatus of claim 1, wherein the clamping electrode has a circular shape and/or comprises first and second electrodes arranged concentrically or side-by-side.

17. A plasma etching apparatus including the electrostatic chuck apparatus of claim 1, and further comprising:
a vacuum chamber including a support member therein, the support member having the electrostatic chuck apparatus thereon;
a baffle plate between the electrostatic chuck apparatus and an inner sidewall of the vacuum chamber;
an exhaust pipe at a lower portion of the vacuum chamber;
a gate valve on an outer sidewall of the vacuum chamber;
a dielectric window in the vacuum chamber spaced apart from the electrostatic chuck apparatus;
an antenna room on the dielectric window, the antenna room comprising at least one antenna therein;
a high-frequency or radio-frequency (RF) power source coupled to the at least one antenna; and
a gas supply source configured to supply a treatment gas into the vacuum chamber via a supply unit at a sidewall of the vacuum chamber.

18-28. (canceled)
